(19) United States
(12) Patent Application Publication
(10) Pub. No.: US 2026/0020632 A1
(43) Pub. Date: Jan. 22, 2026

(54) METHODS FOR GENERATING GARMENT DESIGN DRAWINGS, GARMENT PATTERNS, AND GARMENT PATTERN PIECES

(71) Applicant: ZHEJIANG LINGDI DIGITAL TECHNOLOGY CO., LTD., Hangzhou (CN)

(72) Inventors: Chen LIU, Hangzhou (CN); Gaofeng HE, Hangzhou (CN); Yangyu GAO, Hangzhou (CN); Huamin WANG, Hangzhou (CN); Ruiyang LIU, Hangzhou (CN)

(73) Assignee: ZHEJIANG LINGDI DIGITAL TECHNOLOGY CO., LTD., Hangzhou (CN)

(21) Appl. No.: 19/340,991

(22) Filed: Sep. 26, 2025

Related U.S. Application Data
(63) Continuation of application No. PCT/CN2024/142865, filed on Dec. 26, 2024.

(30) Foreign Application Priority Data
Dec. 28, 2023 (CN) 202311850815.4
Feb. 22, 2024 (CN) 202410203261.7
Jul. 18, 2024 (CN) 202410966265.0

(51) Int. Cl. A41H 3/00; G06N 3/0475

(52) U.S. Cl. CPC A41H 3/007; G06N 3/0475

(57) ABSTRACT

The present disclosure discloses a method for generating a garment design drawing, a method for generating a garment pattern, and a method for generating a garment pattern piece. The method for generating a garment design drawing comprises: receiving design intent data and/or design materials; initializing the design intent data to obtain a visual design drawing; encoding the design materials to obtain a material feature code; generating a target design drawing by inputting the material feature code and/or the visual design drawing into a pre-built generative network; and outputting the target design drawing.

### CROSS-REFERENCE TO RELATED APPLICATIONS

This application is a Continuation of International Patent Application No. PCT/CN2024/142865, filed on Dec. 26, 2024, which claims priority of Chinese Patent Application No. 202311850815.4, entitled “Methods and Devices for Generating a Garment Design Drawing,” filed on Dec. 28, 2023; Chinese Patent Application No. 202410203261.7, entitled “Methods, Devices, Electronic Devices, and Storage Medium for Generating a Garment Pattern,” filed on Feb. 22, 2024; and Chinese Patent Application No. 202410966265.0, entitled “Methods, Devices, Electronic Devices, and Storage Medium for Generating a Garment Pattern Piece,” filed on Jul. 18, 2024, the entire contents of each of which are incorporated herein by reference.

### TECHNICAL FIELD

The present disclosure relates to the field of data processing, garment digitization, and garment design technologies, and in particular, provides methods for generating garment design drawings, garment patterns, and garment pattern pieces.

### BACKGROUND

Garment design is a creative domain that requires a significant convergence of inspiration, continuous attempts, and iterative editing to realize a creative space that is more in line with creative potential and innovation direction. Existing garment design methods are typically implemented by designers using visualization tools such as hand-drawing or CAD software to visualize design concepts. However, in practice, such methods rely heavily on manual editing by designers, which results in long processing times and reduced design efficiency.

In the traditional garment industry, constructing a representation of garment patterns has long been a major challenge. Although a large volume of digitized pattern piece data has been accumulated in the industry, most of such data exists in unstructured formats, which are diverse in form and lack unified standards. This unstructured feature leads to a situation in which designers often need to regenerate patterns when conducting new garment designs, thereby increasing design costs and extending the design cycle. Meanwhile, since the creation of garment pattern pieces is closely related to the personal habits of pattern makers, each pattern maker typically makes the garment pattern pieces based on individual habits and experience. This individual and unsystematic method of inventory management may offer some convenience for individual pattern makers, but from the perspective of enterprise-wide operations, it impedes the standardization of design, and it is also not conducive to the effective management and reuse of digital assets. Furthermore, knowledge transfer and collaboration efficiency remain relatively low.

On the other hand, a comprehensive digital pattern library at the data level often includes flat design drawings of garments, pattern pieces (with sewing information), effect renderings, or photographs of finished garments, aiming to illustrate in detail the structure, dimensional proportions, and design style of the garments. A pattern library is often used in combination with image retrieval algorithms. During design iteration, the closest historically pattern piece data can be retrieved based on similarity, and modifications to the historical data may be made to accelerate the design process.

Existing pattern retrieval systems mainly adopt content-based image retrieval (CBIR) methods. CBIR enables users to perform searches based on actual image content rather than relying on surrounding text descriptions or metadata tags. The main goal of CBIR systems is to retrieve images that are most similar to the query image in terms of content from a large-scale image database. However, CBIR systems typically focus on global features of an image, such as color distribution, texture, and overall shape. When handling localized changes to a specific item in the database, performance may significantly degrade. In other words, CBIR systems are generally incapable of targeting and modifying the components that constitute a garment.

In the garment industry, garment pattern making has consistently been a significant challenge. With the advancement of technology, traditional manual making methods have increasingly revealed their limitations in the context of rapid digitization and personalized demand. As market expectations for finer and more diversified design increase, the manual garment pattern-making method, due to its long-time consumption, high error rate, and low efficiency, has become insufficient to meet the requirements of modern garment production.

To address this problem, pattern-making software such as Richpeace has adopted a symbolic-program-based procedural modeling approach. The software transforms the process of garment pattern making into symbolic drawing based on points, lines, and surfaces, which provides a plurality of advantages, including understandable design parameters, support for stochastic variation, high output quality, and compact representation. Nevertheless, the process of generating the garment pattern is still complex, requiring not only the maker to have profound knowledge of pattern making, but also mathematical reasoning, geometric intuition, and programming skills, which limits the flexibility and general applicability. As a result, the generation process of garment pattern pieces involves high professional skill requirements, while the efficiency of pattern making is low.

### SUMMARY

In view of the above, the present disclosure aims to provide methods for generating garment design drawings, garment patterns, and garment pattern pieces. The methods are capable of automatically generating design drawings without manual editing, thereby improving design efficiency. The methods can achieve garment pattern design based on component-level matching, which avoids the drawbacks caused by direct content-based image retrieval. The methods can also reduce professional skill requirements during the generation of garment pattern pieces while improving pattern-making efficiency.

In a first aspect, the present disclosure provides a method for generating a garment design drawing, comprising: receiving design intent data and/or design materials; initializing the design intent data to obtain a visual design drawing; and/or encoding the design materials to obtain a material feature code; generating a target design drawing by inputting the material feature code and/or the visual design drawing into a pre-built generative network; and outputting the target design drawing.

Furthermore, the design intent data includes one or more of natural language description data, a style drawing, and a line drawing; and the design materials include one or more of a text material, an image material, and a graphic material.

Furthermore, the encoding the design materials to obtain a material feature code includes: determining a target encoder corresponding to each of the design materials; wherein the target encoder includes a text encoder, an image encoder, or a graphics encoder; and encoding the design materials based on the target encoders to obtain the material feature code.

Furthermore, the method further comprising: in response to a modification instruction for the target design drawing, modifying the target design drawing to obtain a modified design drawing; determining the modified design drawing as the design intent data and initializing the design intent data to obtain the visual design drawing; and receiving a new design material and encoding the design materials including the new design material to obtain a material feature code.

In a second aspect, the present disclosure provides a device for generating a garment design drawing, comprising: a receiving unit configured to receive design intent data and/or design materials; an initialization unit configured to initialize the design intent data to obtain a visual design drawing; an encoding unit, configured to encode the design materials to obtain a material feature code; a generation unit, configured to generate a target design drawing by inputting the material feature code and/or the visual design drawing into a pre-built generative network; and an output unit configured to output the target design drawing.

Furthermore, the design intent data includes one or more of natural language description data, a style drawing, and a line drawing; and the design materials include one or more of a text material, an image material, and a graphic material.

Furthermore, the encoding unit includes: a determination sub-unit configured to determine a target encoder corresponding to each of the design materials; wherein the target encoder is a text encoder, an image encoder, or a graphics encoder; and an encoding sub-unit configured to encode the design materials based on the target encoder to obtain the material feature code.

Furthermore, the device for generating a garment design drawing further includes: a modification unit configured to, in response to a modification instruction of the target design drawing, modify the target design drawing to obtain a modified design drawing; and a determination unit configured to determine the modified design drawing as the design intent data and initialize the design intent data to obtain the visual design drawing; wherein the receiving unit further configured to receive a new design material and trigger the encoding unit to encode the design materials including the new design material to obtain the material feature code.

In a third aspect, the present disclosure provides an electronic device, comprising a storage and a processor, wherein the storage is configured to store computer programs, and when the processor executes the computer programs, the processor causes the electronic device to perform the method for generating a garment design drawing according to the first aspect of the present application.

In a fourth aspect, the present disclosure provides a non-transitory computer-readable storage medium storing computer instructions, wherein when a processor reads and executes the computer instructions, the processor executes the method for generating a garment design drawing according to the first aspect of the present application.

The beneficial effects of the above technical solution are as follows: the method and device for generating a garment design drawing are capable of automatically generating the design drawing without manual editing, which improves the design efficiency.

In a fifth aspect, the present disclosure provides a method for generating a garment pattern, comprising: obtaining a digital information carrier of a target garment; and disassembling the digital information carrier of the target garment into component units to obtain the component units of the target garment, and determining the garment pattern of the target garment based on the component units of the target garment.

According to the fifth aspect of the present disclosure, the method obtains a digital information carrier of a target garment, thereby enabling disassembly of the digital information carrier of the target garment into component units to obtain the component units of the target garment, and determining a garment pattern of the target garment based on the component units of the target garment. Compared with the prior art, instead of directly searching for garment pattern data based on images as in existing technologies, the present disclosure introduces an additional step of disassembling component units of a target garment. The garment pattern data of the target garment is then obtained based on the component units of the target garment. In this way, component-level matching can be achieved, thereby avoiding the drawbacks caused by direct content-based image retrieval.

In the fifth aspect, as an optional embodiment, the determining the garment pattern of the target garment based on the component units of the target garment includes: extracting first feature vectors of the component units of the target garment; matching the first feature vectors to obtain similar component units; obtaining stitching lines of the similar component units and pattern information of the similar component units; and determining the garment pattern of the target garment based on the pattern information of the similar component units and the stitching lines of the similar component units.

In this optional embodiment, first feature vectors of the component units of the target garment may be extracted, similar component units may be obtained by matching the first feature vectors, stitching lines of the similar component units and pattern information of the similar component units may be obtained, and the garment pattern of the target garment can be determined based on the pattern information of the similar component units and the stitching lines of the similar component units.

In the fifth aspect, as an optional embodiment, the stitching lines of the similar component units are optimized, wherein an optimization of a stitching line of the similar component units includes modifying a length of the stitching line of the similar component units and modifying a curvature of the stitching line of the similar component units.

In this optional embodiment, a length of the stitching line and a curvature of the stitching line can be adjusted, so as to optimize the length and the curvature of the stitching line.

In the fifth aspect, as an optional embodiment, the method further comprises: determining a silhouette of the target garment based on the digital information carrier of the target garment; and determining the garment pattern of the target garment based on the silhouette of the target garment.

In this optional embodiment, a silhouette of the target garment can also be determined based on the digital information carrier of the target garment, so that the garment pattern of the target garment can be determined based on the silhouette of the target garment.

In a fifth aspect, as an optional embodiment, the method further comprising: constructing a pattern library, the pattern library including at least a component unit library, a component relationship library, a component feature library, and a silhouette feature library, the component unit library being configured to match the similar component units, the component relationship library being configured to match the stitching lines of the similar component units, the component feature library being configured to match the pattern information of the similar component units, and the silhouette feature library being configured to extract the silhouette of the target garment.

In this optional embodiment, a component unit library configured to match the similar component units, a component relationship library configured to match the stitching lines of the similar component units, a component feature library configured to match the pattern information of the similar component units, and a silhouette feature library configured to extract the silhouette of the target garment can be constructed. Meanwhile, by constructing the pattern library, existing garment design resources can be integrated, thereby enabling the digitization of garment design resources, improving the utilization of garment design resources, and reducing barriers to the sharing of garment design resources. Furthermore, the pattern library can improve the efficiency of garment pattern design.

In the fifth aspect, as an optional embodiment, the constructing a pattern library includes: obtaining garment pattern data; and constructing the pattern library based on the garment pattern data.

In this optional embodiment, the pattern library can be constructed based on garment pattern data.

In the fifth aspect, as an optional embodiment, the constructing the pattern library based on the garment pattern data includes: extracting a garment stitching relationship based on the garment pattern data and constructing the component relationship library based on the garment stitching relationship; and disassembling the garment pattern data into the component units to obtain a component disassembly result and constructing the component unit library based on the component disassembly result.

In this optional embodiment, the garment stitching relationship can be extracted based on the garment pattern data, and the component relationship library can be constructed based on the garment stitching relationship. On the other hand, component units can be disassembled based on the garment pattern data to obtain the component disassembly result, and the component unit library can be constructed based on the component disassembly result.

In the fifth aspect, as an optional embodiment, the method further comprises: extracting a global silhouette based on the garment pattern data; encoding the global silhouette based on a feature learning algorithm to obtain a second feature encoding result; and constructing the silhouette feature library based on the second feature encoding result.

In this optional embodiment, the global silhouette can be extracted based on the garment pattern data, the second feature encoding result can be obtained by encoding the global silhouette based on a feature learning algorithm, and the silhouette feature library can be constructed based on the second feature encoding result.

In the fifth aspect, as an optional embodiment, the matching the first feature vectors to obtain similar component units includes: for each of the first feature vectors, matching a plurality of pre-selected elements in the component feature library based on the first feature vector; calculating a similarity between each of the plurality of pre-selected elements and the first feature vectort; determining a highest similarity element based on the similarity between each the plurality of pre-selected elements and the first feature vector; and determining the similar component units based on the highest similarity elements.

In this optional embodiment, a plurality of pre-selected elements can be matched in the component feature library based on the first feature vector. Subsequently, a similarity between each of the pre-selected elements and the first feature vector can be calculated, and based on the similarity between each of the pre-selected elements and the first feature vector, a highest similarity element can be determined. Accordingly, similar component units can be determined based on the highest similarity elements.

In the fifth aspect, as an optional embodiment, the method further comprises: obtaining modification and editing information for the garment pattern of the target garment; and modifying the garment pattern of the target garment based on the modification and editing information.

In this optional embodiment, modification and editing information for the garment pattern of the target garment can be obtained, and the garment pattern of the target garment can be modified based on the modification and editing information, thereby facilitating secondary modification of the target garment by designers.

In a sixth aspect, the present disclosure provides a device for generating a garment pattern, comprising: an obtaining module configured to obtain a digital information carrier of a target garment; and a disassembly module configured to disassemble the digital information carrier of the target garment into component units to obtain the component units of the target garment, and determining a garment pattern of the target garment based on the component units of the target garment.

According to the sixth aspect of the present disclosure, the device obtains a digital information carrier of a target garment, thereby enabling disassembly of the digital information carrier of the target garment into component units to obtain the component units of the target garment, and determining a garment pattern of the target garment based on the component units of the target garment. Compared with the prior art, instead of directly searching for garment pattern data based on images as in existing technologies, the present disclosure introduces an additional step of disassembling component units of a target garment. The garment pattern data of the target garment is then obtained based on the component units of the target garment. In this way, component-level matching can be achieved, thereby avoiding the drawbacks caused by direct content-based image retrieval.

In a seventh aspect, the present disclosure provides an electronic device comprising: a processor; and a storage configured to store machine-readable instructions, when the processor executes the machine-readable instructions, the processor performs the method for generating a garment pattern according to any aforementioned embodiment.

According to the seventh aspect of the present disclosure, the electronic device performs the method for generating a garment pattern, and is thereby capable of obtaining a digital information carrier of a target garment, disassembling the digital information carrier of the target garment into component units to obtain the component units of the target garment, and determining a garment pattern of the target garment based on the component units of the target garment. Compared with the prior art, instead of directly searching for garment pattern data based on images as in existing technologies, the present disclosure introduces an additional step of disassembling component units of a target garment. The garment pattern data of the target garment is then obtained based on the component units of the target garment. In this way, component-level matching can be achieved, thereby avoiding the drawbacks caused by direct content-based image retrieval.

In an eighth aspect, the present disclosure provides a non-transitory computer-readable storage medium storing computer programs, wherein the computer programs are executed by a processor to perform the method for generating a garment pattern according to any aforementioned embodiment.

According to the eighth aspect of the present disclosure, the storage medium performs the method for generating a garment pattern, and is thereby capable of obtaining a digital information carrier of a target garment, disassembling the digital information carrier of the target garment into component units to obtain the component units of the target garment, and determining a garment pattern of the target garment based on the component units of the target garment. Compared with the prior art, instead of directly searching for garment pattern data based on images as in existing technologies, the present disclosure introduces an additional step of disassembling component units of a target garment. The garment pattern data of the target garment is then obtained based on the component units of the target garment. In this way, component-level matching can be achieved, thereby avoiding the drawbacks caused by direct content-based image retrieval.

In an ninth aspect, the present disclosure provides a method for generating a garment pattern piece, comprising: receiving a garment design language and converting the garment design language into a symbolic pattern-making language using a target language parsing model; converting the symbolic pattern-making language into a drawing command corresponding to a target pattern-making software using a target symbol translation model; and determining a target garment pattern piece based on the drawing command.

Compared with related technologies, in the method for generating a garment pattern piece provided in the embodiments of the present disclosure, after a garment design language is received from a user, the garment design language is converted into a drawing command corresponding to target pattern-making software by using a target language parsing model and a target symbol translation model. A target garment pattern piece is then generated based on the drawing command. During the pattern-making process, the user only needs to input the garment design language, which may be, for example, natural language, a design draft, or a photograph. As a result, the requirement for professional skills in the generation of garment pattern pieces is reduced. Meanwhile, due to the high level of automation in the entire pattern-making process, the user can perform a large volume of garment pattern-making tasks simultaneously, thereby improving overall pattern-making efficiency. In addition, because the transformation logic for converting the garment design language into a symbolic pattern-making language is significantly different from that for converting the symbolic pattern-making language into a drawing command, the garment design language is first converted into a symbolic pattern-making language using the target language parsing model, and then the symbolic pattern-making language is converted into a drawing command using the target symbol translation model. By using the symbolic pattern-making language as an intermediate representation, the operational logic of the target language parsing model and the target symbol translation model becomes clearer, the training process is simplified, and the amount of data required for training is reduced.

In optional embodiments, before converting the symbolic pattern-making language into the drawing command using the target symbol translation model, the method further comprises: determining the target symbol translation model based on the target pattern-making software. For different types of target pattern-making software, a corresponding target symbol translation model is selected to generate drawing commands. Each target symbol translation model is used exclusively to generate drawing commands corresponding to a specific type of target pattern-making software, which avoids confusion between the grammar rules of different types of pattern-making software, reduces the possibility that the target symbol translation model generates drawing commands that do not comply with the grammar rules of the target pattern-making software, ensures better compatibility between the drawing commands generated by the target symbol translation model and the target pattern-making software used in subsequent steps, and improves the pattern-making quality of the target pattern-making software.

In optional embodiments, the determining the target symbol translation model based on the target pattern-making software includes the following operations. A target pattern-making grammar rule of the target pattern-making software is obtained; an initial symbol translation model is obtained; and the initial symbol translation model is trained using the target pattern-making grammar rule to obtain the target symbol translation model. By performing model training of the target symbol translation model based on real-time acquisition of the target pattern-making grammar rule of the target pattern-making software, the target symbol translation model can be updated accordingly when the target pattern-making grammar rule changes, which enhances the compatibility between the drawing commands generated by the target symbol translation model and the target pattern-making software, thereby improving the pattern-making quality of the target pattern-making software.

In optional embodiments, the determining the target symbol translation model based on the target pattern-making software includes the following operations. A preset symbol translation model list is obtained, wherein the preset symbol translation model list includes a plurality of sample symbol translation models and sample pattern-making software corresponding to each of the plurality of sample symbol translation models; and a sample symbol translation model corresponding to the target pattern-making software in the preset symbol translation model list is determined as the target symbol translation model. By predefining a symbol translation model list that includes a plurality of pre-trained sample symbol translation models and sample pattern-making software corresponding to each of the sample symbol translation models, the target symbol translation model can be determined directly by selecting the sample symbol translation model corresponding to the target pattern-making software from the symbol translation model list, which eliminates the need for retraining the model and improves the efficiency of determining the target symbol translation model.

In optional embodiments, the determining a target garment pattern piece based on the drawing command includes the following operations. The drawing command is input into the target pattern-making software, and a garment pattern piece is received, the garment pattern piece being generated by the target pattern-making software. Whether the garment pattern piece meets a preset pattern-making rule is determined using a quality inspection model. In response to determining that the garment pattern piece does not meet the preset pattern-making rule, the drawing command is adjusted according to the preset pattern-making rule. The adjusted drawing command is input into the target pattern-making software, and the target garment pattern piece is received, the target garment pattern piece being generated by the target pattern-making software. In response to determining that the garment pattern piece meets the preset pattern-making rule, the garment pattern piece is used as the target garment pattern piece. After the garment pattern piece is generated based on the drawing command, a quality inspection model is used to detect the generated garment pattern piece and determine whether the garment pattern piece complies with preset pattern-making rules. If the garment pattern piece does not comply with the preset pattern-making rules, the drawing command is adjusted based on the preset pattern-making rules, and a target garment pattern piece is generated again based on the adjusted drawing command. This ensures that the generated target garment pattern piece better complies with the preset pattern-making rules, thereby improving the pattern-making quality of the target garment pattern piece.

In optional embodiments, the target language parsing model and the quality inspection model are large multimodal models. The target language parsing model and the quality inspection model are the same large multimodal model, which reduces the training process and the training needs of the model, and improves the efficiency of the board making while reducing the cost of the board making.

In optional embodiments, the method for generating a garment pattern piece further comprising: receiving a modified garment design language and converting the modified garment design language into a modified symbolic pattern-making language using the target language parsing model; converting the modified symbolic pattern-making language into a modified drawing command using the target symbol translation model; and modifying the target garment pattern piece according to the modified drawing command. After the target garment pattern piece is generated, a modified garment design language input by the user is further received, and a modified drawing command is generated based on the modified garment design language to modify the target garment pattern piece, thereby enabling convenient modification of the target garment pattern piece.

In a tenth aspect, embodiments of the present disclosure provide a device for generating a garment pattern piece, comprising: a language parsing module configured to receive a garment design language and convert the garment design language into a symbolic pattern-making language using a target language parsing model; a symbol translation module configured to convert the symbolic pattern-making language into a drawing command corresponding to target pattern-making software using a target symbol translation model; and a pattern-making module configured to determine a target garment pattern piece based on the drawing command.

Compared with the prior art, in the garment pattern piece generation device provided in the embodiments of the present disclosure, after a garment design language is received by the language parsing module, the garment design language is converted into a drawing command using a target language parsing model in the language parsing module and a target symbol translation model in the symbol translation module. Finally, pattern-making software in the pattern-making module is used to generate a target garment pattern piece based on the drawing command. During the pattern-making process, the user only needs to input the garment design language, which may include, for example, natural language, design drafts, or photographs. As a result, the requirement for professional skills in the preparation of garment pattern pieces is reduced. Meanwhile, due to the high level of automation in the entire pattern-making process, the user can perform a large volume of garment pattern-making tasks simultaneously, thereby improving overall pattern-making efficiency.

In an eleventh aspect, embodiments of the present disclosure provide an electronic device, comprising: at least one processor; and a storage in communication with the at least one processor, wherein the storage stores instructions executable by the at least one processor that, when executed by the at least one processor, cause the at least one processor to perform the aforementioned method for generating a garment pattern piece.

In a twelfth aspect, embodiments of the present disclosure provide a non-transitory computer-readable storage medium storing computer programs that, when executed by a processor, cause the processor to perform the aforementioned method for generating a garment pattern piece.

In a thirteenth aspect, embodiments of the present disclosure provide a computer program product, comprising computer program code that, when executed by a computer device, causes the computer device to execute the aforementioned method for generating a garment pattern piece.

Other features and advantages of the present disclosure will be described in the following specification. The objectives and other advantages of the present disclosure can be achieved and obtained through the structures particularly pointed out in the written specification and the accompanying drawings.

### BRIEF DESCRIPTION OF THE DRAWINGS

In order to more clearly illustrate the technical solutions of the embodiments of the present disclosure, a brief introduction to the drawings required in the embodiments is provided below. It should be understood that the following drawings only illustrate certain embodiments of the present disclosure and therefore should not be regarded as limiting the scope. For those skilled in the art, other related drawings may also be obtained based on these drawings without creative efforts. The above and other objectives, features, and advantages of the present disclosure will become more apparent from the drawings.

FIG. 1 is a flowchart illustrating a method for generating a garment design drawing according to an embodiment of the present disclosure.

FIG. 2 is a flowchart illustrating another method for generating a garment design drawing according to an embodiment of the present disclosure.

FIG. 3 is a schematic diagram illustrating a structure of a device for generating a garment design drawing according to an embodiment of the present disclosure.

FIG. 4 is a schematic diagram illustrating a structure of another device for generating a garment design drawing according to an embodiment of the present disclosure.

FIG. 5 is a flowchart illustrating a portion of the method for generating a garment design drawing according to an embodiment of the present disclosure.

FIG. 6 is a flowchart illustrating a process for generating a material feature code based on design materials according to an embodiment of the present disclosure.

FIG. 7 is a flowchart illustrating a process for generating a garment design drawing based on a generative model according to an embodiment of the present disclosure.

FIG. 8 is a flowchart illustrating a method for generating a garment pattern according to an embodiment of the present disclosure.

FIG. 9 is a schematic diagram illustrating a construction of a garment pattern according to an embodiment of the present disclosure.

FIG. 10 is a flowchart illustrating a feature matching process according to an embodiment of the present disclosure.

FIG. 11 is a schematic diagram illustrating another construction of a garment pattern according to an embodiment of the present disclosure.

FIG. 12 is a schematic diagram illustrating a construction of a pattern library according to an embodiment of the present disclosure.

FIG. 13 is a schematic diagram illustrating a structure of a device for generating a garment pattern according to an embodiment of the present disclosure.

FIG. 14 is a schematic diagram illustrating a structure of an electronic device according to an embodiment of the present disclosure.

FIG. 15 is a flowchart illustrating a method for generating a garment pattern piece according to a first embodiment of the present disclosure.

FIG. 16 is a schematic diagram illustrating design drafts and finished garment photographs in the method for generating a garment pattern piece according to the first embodiment of the present disclosure.

FIG. 17 is a schematic diagram illustrating a structure of a target language parsing model in the method for generating a garment pattern piece according to the first embodiment of the present disclosure.

FIG. 18 is a flowchart illustrating a method for generating a garment pattern piece according to another embodiment of the present disclosure.

FIG. 19 is a flowchart illustrating a process for determining a target garment pattern piece in the method for generating a garment pattern piece according to the first embodiment of the present disclosure.

FIG. 20 is a flowchart illustrating a method for generating a garment pattern piece according to a second embodiment of the present disclosure.

FIG. 21 is a schematic diagram illustrating a structure of a device for generating a garment pattern piece according to a third embodiment of the present disclosure.

FIG. 22 is a schematic diagram illustrating a structure of an electronic device according to a fourth embodiment of the present disclosure.

### DETAILED DESCRIPTION

The technical solutions of the embodiments of the present disclosure will be described below in conjunction with the accompanying drawings. Obviously, the embodiments described are only part of the embodiments of the present disclosure and not all of them. The following embodiments are provided merely by way of example for more clearly illustrating the technical solutions of the present disclosure, and should not be construed as limiting the scope of protection of the present disclosure. In addition, if the terms “first,” “second,” and the like appear, they are used solely for the purpose of distinguishing descriptions and should not be understood as indicating or implying relative importance. It will be understood by those skilled in the art that, where there is no conflict, the following embodiments and the features in the embodiments may be combined with one another.

### Embodiment 1

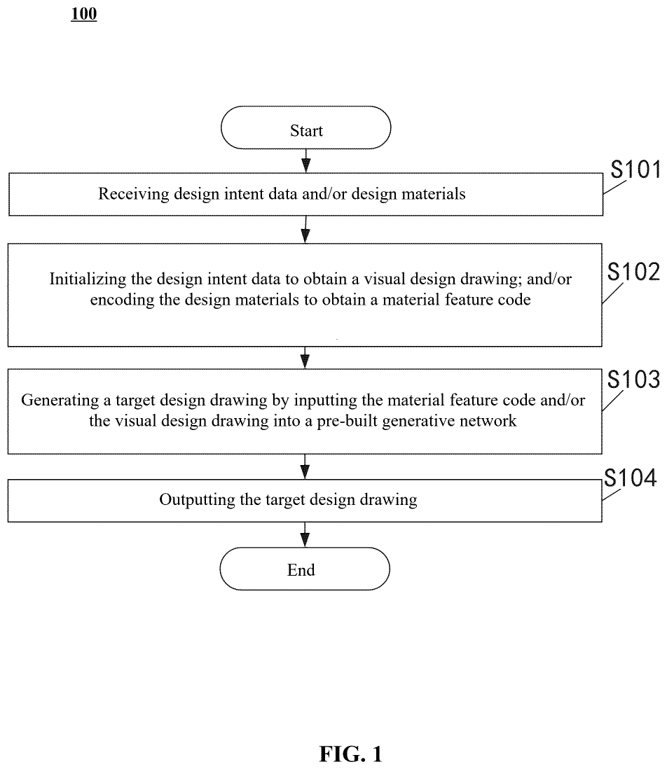

Please refer to FIG. 1, wherein FIG. 1 is a flowchart illustrating a method for generating a garment design drawing according to an embodiment of the present disclosure. The method for generating a garment design drawing comprises the following operations.
S101, design intent data and/or design materials may be received.

In the present embodiment, the design intent data includes one or more of natural language description data, a style drawing, and a line drawing.

In the present embodiment, the design materials include one or more of a text material, an image material, and a graphic material.
S102, the design intent data may be initialized to obtain a visual design drawing, and/or the design materials may be encoded to obtain a material feature code.
S103, a target design drawing may be generated by inputting the material feature code and/or the visual design drawing into a pre-built generative network.
S104, the target design drawing may be output.

In the present embodiment, the execution subject of the method may be a computing device such as a computer or a server, which is not limited in this embodiment.

In the present embodiment, the execution subject of the method may also be an intelligent device such as a smartphone or a tablet, which is not limited in this embodiment.

It can be seen that the method for generating a garment design drawing described in the present embodiment can recognize the design intent of a designer or user and rapidly output a visual style design effect based on the design intent, thereby achieving an intuitive expression of creative ideas. Meanwhile, the method supports multiple material sources, so that the design details from multiple sources can be integrated, thereby achieving a more diverse, explicit, and controllable creative design space and improving the generation effect of the design drawing.

### Embodiment 2

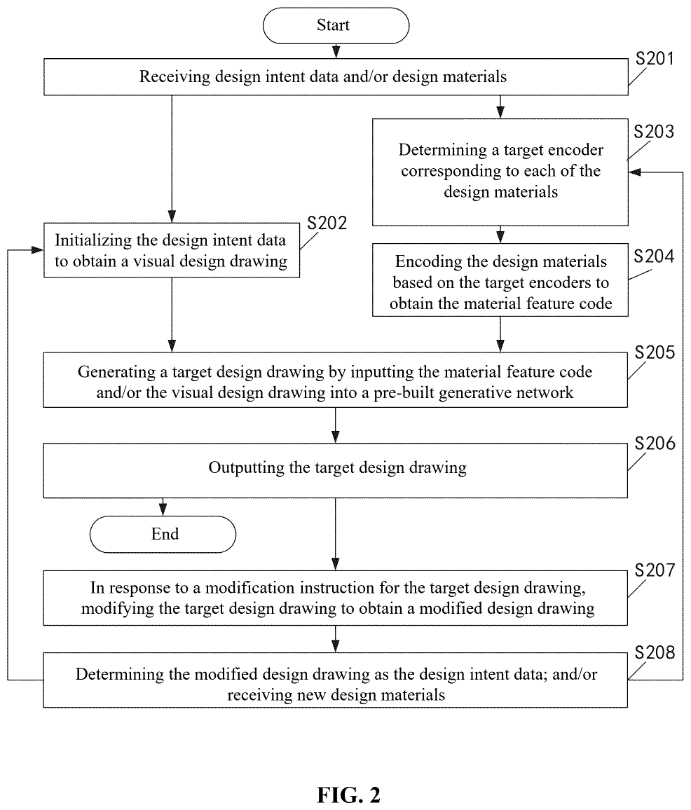

Please refer to FIG. 2, wherein FIG. 2 is a flowchart illustrating another method for generating a garment design drawing according to an embodiment of the present disclosure. The method for generating a garment design drawing comprises the following operations.
S201, design intent data and/or design materials may be received, following which operations S202 and/or S203˜S204 may be performed.

In the present embodiment, the design intent data includes one or more of natural language description data, a style drawing, and a line drawing.

In the present embodiment, the design materials include one or more of a text material, an image material, and a graphic material.
S202, the design intent data may be initialized to obtain a visual design drawing, following which operation S205 is performed.

In the present embodiment, the method performs initialization design on the design intent and converts it into a visual design drawing. Specifically, the method may identify the content within the design intent data and perform initialization design based on the content using a generative model to obtain the visual design drawing. This process may involve user interaction to achieve an interactive initialization effect, or the visual design drawing may be automatically generated entirely by the generative model.

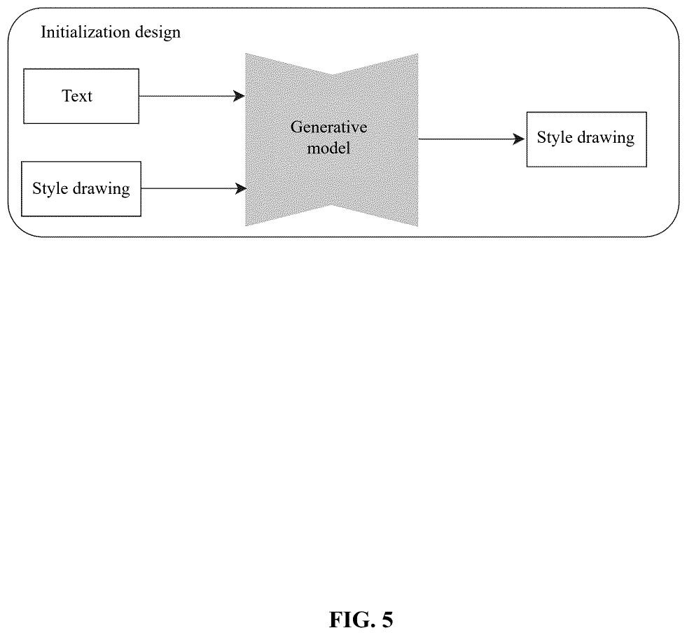

In the present embodiment, generating the visual design drawing using the generative model is a core operation of the present disclosure. In a computer system, the unit performing this process may be regarded as a minimal design unit, and the structure thereof is illustrated in FIG. 5.

Operations S201 to S202 enable an initial understanding of the intent of the designer or user (such as design concepts and creative ideas), and a visual design drawing that satisfies design preview effects can be obtained, thereby achieving an effect of intuitive expression. Specifically, the visual design drawing may include detailed effects such as design colors, techniques, details, and textures.
S203, a target encoder corresponding to each of the design materials may be determined, wherein the target encoder includes a text encoder, an image encoder, or a graphics encoder.

In the present embodiment, the target encoder is a model configured to convert design materials into corresponding codes. This model is enhanced through training with vertical industry data related to fashion, garments, design, fabrics, or the like. Accordingly, the model is more professional and targeted. In addition, the model can better keep up with current trends and creative directions, thereby achieving stronger feature representation capabilities.
S204, the design materials may be encoded based on the target encoders to obtain the material feature code, after which operation S205 is performed.
S205, a target design drawing may be generated by inputting the material feature code and/or the visual design drawing into a pre-built generative network.

In the present embodiment, for the style design drawing obtained by converting the design intention, the method can provide additional inspiration material inputs (i.e., output design materials), so as to incorporate more creative elements into the design drawing and generate a target design drawing that better meets the design requirements.

In the present embodiment, the method supports the individual or combined use of other material carriers such as texts, images, and graphics. Each of the texts, images, and graphics is encoded using a different modality encoder to obtain a tensorized feature.

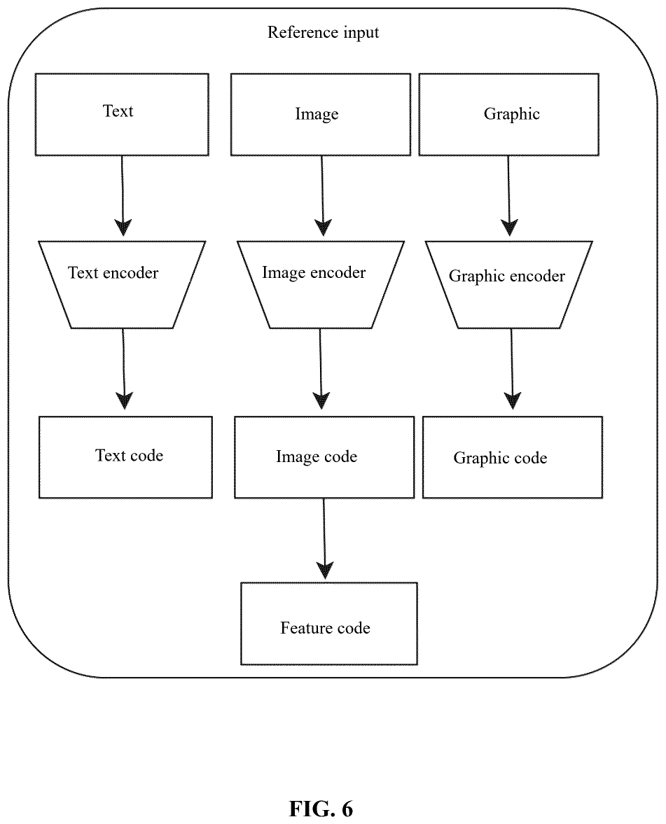

As shown in FIG. 6, FIG. 6 is a flowchart illustrating a process for generating a material feature code based on design materials according to an embodiment of the present disclosure. Based on the above process, the method can achieve the unification and fusion of information from inspiration materials of different modalities, thereby providing the generation model with more effective and better-determined prior information, which facilitates better generation of the target design drawing.
S206, the target design drawing may be output.

By implementing operations S203 to S206, the fusion of input information from different modalities, different design materials, and various sources of inspiration may be achieved, thereby achieving the effect of integrating design elements. As a result, the generation model can extensively absorb the space of design elements, enabling the editing, modification, and effect optimization of the global effect and local detail effect of the design drawing.

Specifically, since the generation model can accurately and controllably capture design elements and iteratively edit them with the design drawing, the target design drawing can better meet the design requirements and achieve a richer, more intuitive, and three-dimensional presentation effect.
S207, in response to a modification instruction for the target design drawing, the target design drawing may be modified to obtain a modified design drawing.
S208, the modified design drawing may be determined as the design intent data, and operation S202 may be performed; and/or new design materials may be received, and operation S203 may be performed.

In the present embodiment, the method can realize iterative and repeated modification and editing of the style design drawing, thereby enhancing the design intention and obtaining a target design drawing that better meets the requirements.

In this embodiment, since each iteration can incorporate more design intentions and creative ideas, the method enables more flexible realization of either divergent or convergent design effects. It may thus be seen that the method has a wide range of application scenarios and improved practicability.

In addition, the method can achieve design drawing editing effects with different granularities during the iterative process through global editing, local editing, and other approaches, thereby further improving the implementation flexibility and expression accuracy of the method, and meeting the needs of designers and users for design drawing editing in a wider variety of scenarios.

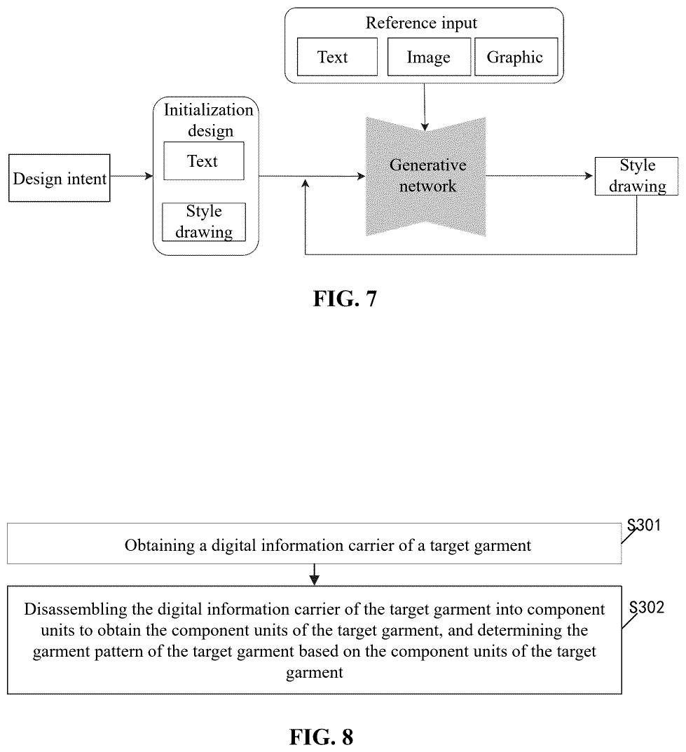

Please refer to FIG. 7, wherein FIG. 7 is a flowchart illustrating a process for generating a garment design drawing based on a generative model. In this process, the design drawing can be quickly designed, supplemented, refined, and edited again in a visualized manner, thereby enabling iterative design of the garment design drawing and producing diverse and highly creative garment design effects to meet the needs of designers and other groups.

In the present embodiment, the method may be executed by a computing device such as a computer or a server, which is not limited herein.

In the present embodiment, the execution subject of the method may also be a smart device such as a smartphone, a tablet computer, etc., which is not limited herein.

The method for generating a garment design drawing described in this embodiment can recognize the design intention of a designer or user and quickly output a visualized style design effect based on the design intention, thereby enabling an intuitive expression of creative ideas. At the same time, the method supports multiple types of material sources, so that design details from different sources may be integrated, thereby creating a more diverse, explicit, and controllable design space and improving the generation effect of the design drawing. Finally, the method also supports iterative editing and modification of the design drawing, realizing progressive editing and refinement of the design drawing, which facilitates targeted understanding of the design intention and thus enhances the expressive effectiveness of the design renderings.

### Embodiment 3

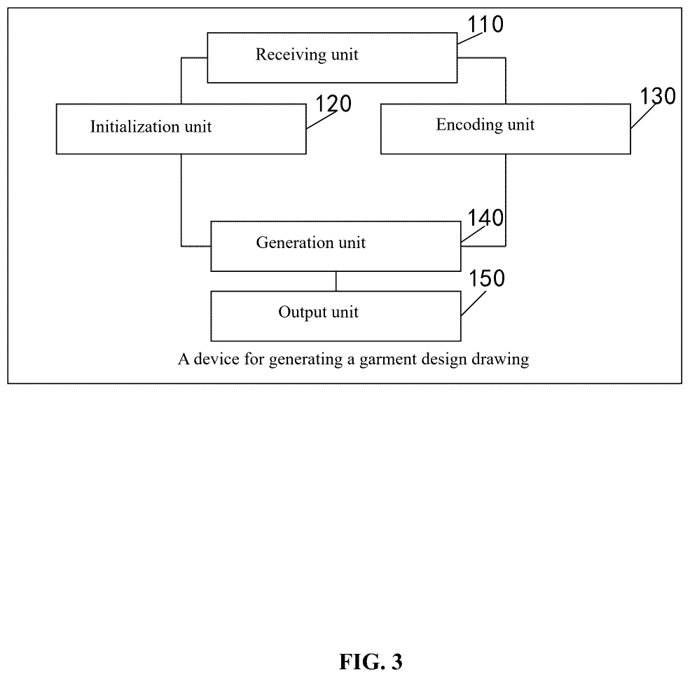

Referring to FIG. 3, FIG. 3 is a schematic diagram illustrating a structure of a device for generating a garment design drawing according to an embodiment of the present disclosure. As shown in FIG. 3, a device for generating a garment design drawing comprises the following units.

A receiving unit 110 is configured to receive design intent data and/or design materials.

An initialization unit 120 is configured to initialize the design intent data to obtain a visual design drawing.

An encoding unit 130 is configured to encode the design materials to obtain a material feature code.

A generation unit 140 is configured to generate a target design drawing by inputting the material feature code and/or the visual design drawing into a pre-built generative network. An output unit 150 is configured to output the target design drawing.

In the present embodiment, the description and explanation of the device for generating a garment design drawing may refer to the descriptions in embodiment 1 or embodiment 2, and will not be repeated herein.

It can be seen that the device for generating a garment design drawing described in the present embodiment can identify a design intention of a designer or a user, and quickly output a visualized style design effect based on the design intention, thereby achieving an intuitive expression of creative ideas. Meanwhile, the device supports multiple material sources, such that design details from various sources can be integrated, thereby realizing a more diverse, explicit, and controllable design creativity space, and improving the generation effect of the design drawings.

### Embodiment 4

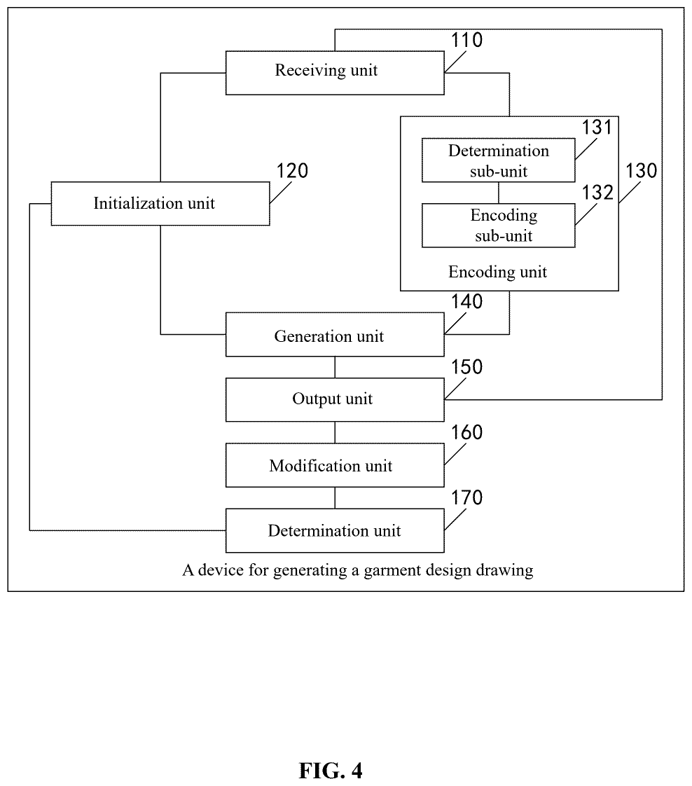

Referring to FIG. 4, FIG. 4 is a schematic diagram illustrating a structure of another device for generating a garment design drawing according to an embodiment of the present disclosure. As shown in FIG. 4, the device for generating a garment design drawing comprises the following units.

A receiving unit 110 is configured to receive design intent data and/or design materials.

An initialization unit 120 is configured to initialize the design intent data to obtain a visual design drawing,

An encoding unit 130 is configured to encode the design materials to obtain a material feature code.

A generation unit 140 is configured to generate a target design drawing by inputting the material feature code and/or the visual design drawing into a pre-built generative network.

An output unit 150 is configured to output the target design drawing.

In the present embodiment, the design intent data includes one or more of natural language description data, a style drawing, and a line drawing.

The design materials include one or more of a text material, an image material, and a graphic material.

As an optional embodiment, the encoding unit 130 includes the following units.

A determination sub-unit 131 is configured to determine a target encoder corresponding to each of the design materials, wherein the target encoder is a text encoder, an image encoder, or a graphics encoder.

An encoding sub-unit 132 is configured to encode the design materials based on the target encoder to obtain the material feature code.

As an optional embodiment, the device for generating a garment design drawing further includes the following units.

A modification unit 160 is configured to modify the target design drawing in response to a modification instruction for the target design drawing to obtain a modified design drawing.

A determination unit 170 is configured to determine the modified design drawing as the design intent data and trigger the initialization unit 120 to initialize the design intent data to obtain the visual design drawing.

The receiving unit 110 is further configured to receive a new design material and trigger the encoding unit 130 to encode the design materials including the new design material to obtain the material feature code.

In the present embodiment, the explanations and descriptions regarding the device for generating a garment design drawing may refer to Embodiment 1 or Embodiment 2, and are not repeated herein.

The device for generating a garment design drawing described in the present embodiment can identify the design intention of a designer or a user, and quickly output a visualized style design effect based on the design intention, thereby achieving an intuitive expression of creative ideas. Meanwhile, the device supports multiple types of material sources, so that design details from various sources can be integrated, thereby realizing a more diversified, explicit, and controllable design creativity space, and improving the generation effect of the design drawing. Furthermore, the device also supports iterative editing and modification of the design drawing, enabling progressive editing and refinement of the design drawing, which facilitates targeted understanding of the design intention and improves the expressive effectiveness of the design rendering.

The present embodiment provides an electronic device, wherein the electronic device comprises a memory and a processor, the memory is configured to store computer programs, and the processor is configured to execute the computer programs to perform the method for generating a garment design drawing as described in Embodiment 1 or Embodiment 2 of the present disclosure.

The present embodiment further provides a non-transitory computer-readable storage medium storing computer instructions, wherein the computer instructions, when executed by a processor, cause the processor to perform the method for generating a garment design drawing as described in Embodiment 1 or Embodiment 2 of the present disclosure.

### Embodiment 5

Referring to FIG. 8, FIG. 8 is a flowchart illustrating a method for generating a garment pattern according to an embodiment of the present disclosure. As shown in FIG. 8, a method for generating a garment pattern comprises the following operations.
S301, a digital information carrier of a target garment may be obtained.
S302, the digital information carrier of the target garment may be disassembled into component units to obtain the component units of the target garment, and the garment pattern of the target garment may be determined based on the component units of the target garment.

The method according to the present embodiment can obtain a digital information carrier of a target garment, disassemble the digital information carrier of the target garment into component units to obtain the component units of the target garment, and determine the garment pattern of the target garment based on the component units of the target garment. Compared with the prior art, in contrast to the conventional method that directly searches for garment pattern data based on images, the present disclosure introduces a component unit disassembly operation of the target garment. The garment pattern data of the target garment is then obtained based on the component units of the target garment, thereby enabling component-level matching and avoiding the drawbacks caused by direct content-based image retrieval.

In the embodiment of the present disclosure, as an example, assuming that a pattern maker needs to create a pattern for a shirt of style A. The pattern maker may input a digital information carrier of the shirt of style A, thereby disassembling the shirt of style A into component units, such as a collar component unit, a waist component unit, and so on. Finally, a garment pattern of the shirt of style A is generated based on the disassembly result.

Furthermore, in some scenarios, if the garment pattern of the shirt of style A does not match the pattern envisioned by the pattern maker, the pattern maker may need to make secondary modifications to the matched garment pattern of the shirt of style A. In the prior art, the garment pattern of the shirt of style A is not obtained through component-level matching, but through direct image search. As a result, the pattern maker cannot make secondary modifications to a specified component unit. However, in the present disclosure, assuming that the garment pattern of the shirt of style A includes component unit S1 and component unit S2, which together constitute the shirt of style A, the pattern maker may replace component unit S1with component unit S3 as needed, without having to redesign the pattern for component unit S2. Accordingly, in the prior art, since the pattern of the shirt of style A is obtained directly based on an image and is not disassembled into multiple component units, it is difficult to perform independent secondary modification on a specific component unit. In contrast, the present disclosure enables secondary modification of an individual component unit.

In the embodiment of the present disclosure, the garment pattern of the target garment may be used to construct a three-dimensional model of the target garment, thereby presenting the finished garment of the target garment.

In the embodiment of the present disclosure, the target garment may be a shirt, a cotton-padded jacket, or other styles of garments.

In the embodiment of the present disclosure, the digital information carrier of the target garment may be an image of the target garment, a design sketch of the target garment, or a pattern design drawing of the target garment. The pattern design drawing of the target garment may be incomplete, in which case a complete pattern of the target garment may be obtained from a pattern library. Of course, the pattern design drawing of the target garment may also be complete, in which case the pattern design drawing of the target garment may be represented as digital information through the pattern library.

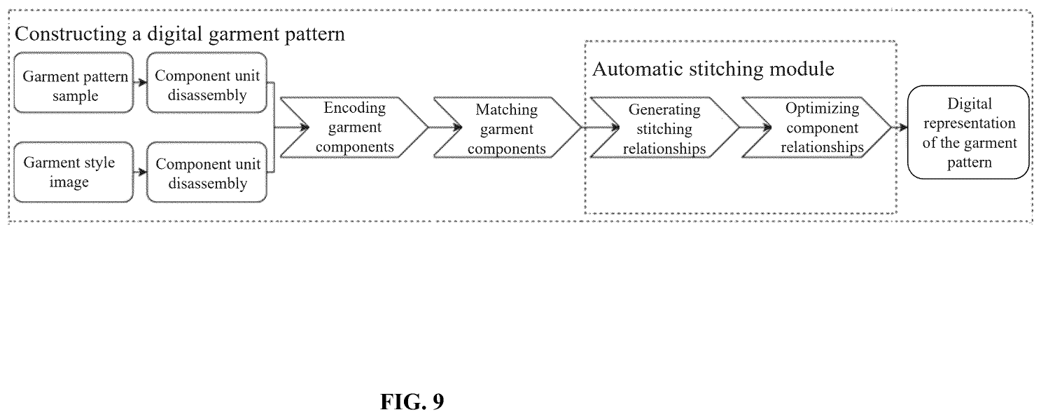

In the embodiment of the present disclosure, referring to FIG. 9, FIG. 9 is a schematic diagram illustrating a construction of a garment pattern according to an embodiment of the present disclosure. As shown in FIG. 9, a pattern maker may use a garment pattern sample or a garment style drawing as a digital information carrier of a target garment, and obtain a garment pattern representation of the target garment by performing component unit disassembly or load unit disassembly, auxiliary component encoding, and garment component matching.

In the embodiment of the present disclosure, as an optional embodiment, the determining the garment pattern of the target garment based on the component units of the target garment includes the following operations.

First feature vectors of the component units of the target garment are extracted.

The first feature vectors are matched to obtain similar component units.

Stitching lines of the similar component units and pattern information of the similar component units are obtained.

The garment pattern of the target garment is determined based on the pattern information of the similar component units and the stitching lines of the similar component units.

In this optional embodiment, by extracting the first feature vectors of the component units of the target garment, similar component units can be obtained by matching the first feature vectors. Subsequently, stitching lines of the similar component units and pattern information of the similar component units can be obtained. Accordingly, the garment pattern of the target garment can be determined based on the pattern information of the similar component units and the stitching lines of the similar component units.

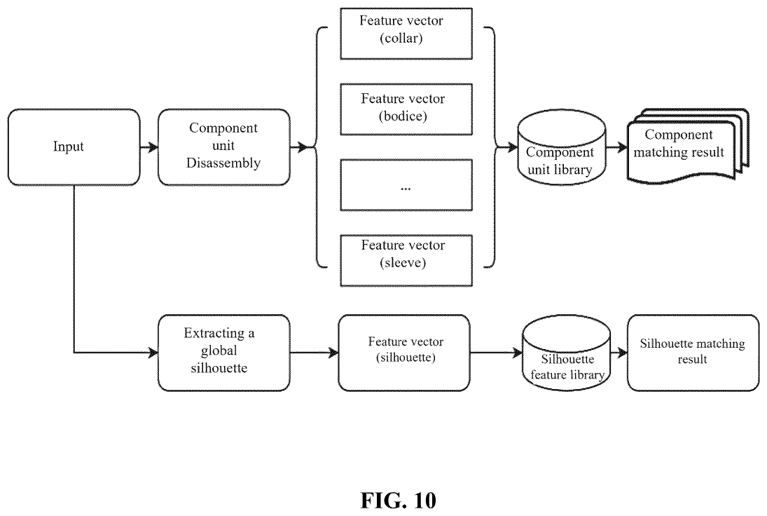

For the above optional embodiment, as an example, please refer to FIG. 10. FIG. 10 is a flowchart illustrating a feature matching process according to an embodiment of the present disclosure. As shown in FIG. 10, through component unit disassembly, feature vectors of the collar, the body, and the sleeve can be extracted based on the disassembly result, wherein the feature vector of the collar, the feature vector of the body, and the feature vector of the sleeve are vectors in the first feature vectors. On the other hand, similar component units of the target garment, that is, a component matching result, can be obtained by matching based on the first feature vectors.

In the embodiment of the present disclosure, as an optional embodiment, the method further comprises the following operations. The stitching lines of the similar component units may be optimized, wherein an optimization of a stitching line of the similar component units is performed by modifying a length of the stitching line of the similar component units and modifying a curvature of the stitching line of the similar component units.

In this optional embodiment, a length of the stitching line and a curvature of the stitching line may be adjusted, thereby optimizing the length and curvature of the stitching line.

For the above optional embodiment, please refer to FIG. 11. FIG. 11 is a schematic diagram illustrating another construction of a garment pattern according to an embodiment of the present disclosure. As shown in FIG. 11, after the stitching relationship is synthesized, a component relationship can be optimized, that is, a length of a stitching line and a curvature of the stitching line can be adjusted based on a component feature library, wherein the component feature library can record the length and curvature of the stitching line corresponding to each style of component.

In the embodiment of the present disclosure, as an optional embodiment, the method according to the embodiment of the present disclosure further comprises the following operations.

A silhouette of the target garment is determined based on the digital information carrier of the target garment.

The garment pattern of the target garment is determined based on the silhouette of the target garment.

For the above optional embodiment, in some scenarios, the target garment may not be disassembled into component units. In such cases, the garment pattern of the target garment can be determined based on the silhouette of the target garment.

In the embodiment of the present disclosure, as an optional embodiment, the determining the garment pattern of the target garment based on the silhouette of the target garment includes the following operations.

Second feature vectors of the target garment are extracted from the silhouette of the target garment based on a feature extractor.

The second feature vectors are matched with a silhouette feature library to obtain a silhouette most similar to the silhouette of the target garment.

The garment pattern of the target garment is determined based on the silhouette most similar to the silhouette of the target garment.

The optional embodiment may further determine a silhouette of the target garment based on the digital information carrier of the target garment, and determine the garment pattern of the target garment based on the silhouette of the target garment.

In the embodiment of the present disclosure, as an optional embodiment, the method of the present embodiment of the present disclosure further comprises the following operations.

A pattern library is constructed, the pattern library including at least a component unit library, a component relationship library, a component feature library, and a silhouette feature library. The component unit library is configured to match similar component units. The component relationship library is configured to match the stitching lines of the similar component units. The component feature library is configured to match the pattern information of the similar component units. The silhouette feature library is configured to extract the silhouette of the target garment.

The optional embodiment may construct a component unit library for matching similar component units, a component relationship library for matching stitching lines of the similar component units, a component feature library for matching pattern information of the similar component units, and a silhouette feature library for extracting the silhouette of the target garment. Meanwhile, by constructing a pattern library, existing garment design resources can be integrated, thereby achieving digitization of the garment design resources, improving the utilization of the garment design resources, and reducing barriers to sharing the garment design resources. Furthermore, the pattern design efficiency can be improved through the pattern library.

For the above optional embodiment, as an example, it is assumed that a pattern maker needs to make a pattern for a shirt of style B, which is a modified version of a shirt of style A. If the pattern library is not constructed, the pattern maker needs to completely remake the pattern for the shirt of style B. However, if the pattern library is constructed based on the shirt of style A, the pattern maker can first use the pattern of the shirt of style A as a similar pattern for the shirt of style B based on the pattern library, and then perform secondary modification on the similar pattern of the shirt of style B to obtain the final pattern of the shirt of style B. In this way, there is no need to completely remake the pattern for the shirt of style B. Therefore, by integrating the existing garment design resources, i.e., the shirt of style A, the digitization of the garment design resources can be achieved, thereby improving the utilization of the garment design resources and reducing the barriers to sharing the garment design resources.

In the embodiment of the present disclosure, as an optional embodiment, the constructing a pattern library includes the following operations.

Garment pattern data is obtained.

The pattern library is constructed based on the garment pattern data.

The optional embodiment may obtain garment pattern data and construct a pattern library based on the garment pattern data.

In the optional embodiment described above, the garment pattern data refers to historical garment pattern data, wherein the historical garment pattern data includes digital information carriers such as pattern design sketches, garment style drawings, and physical images of garments.

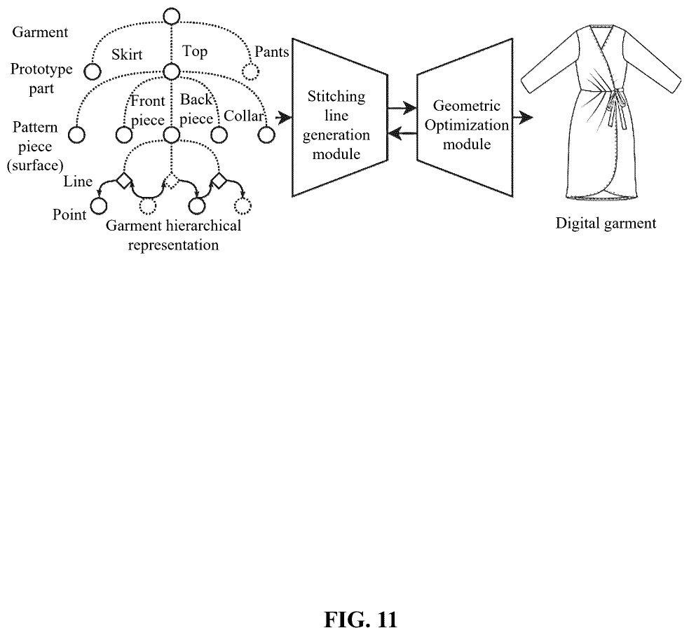

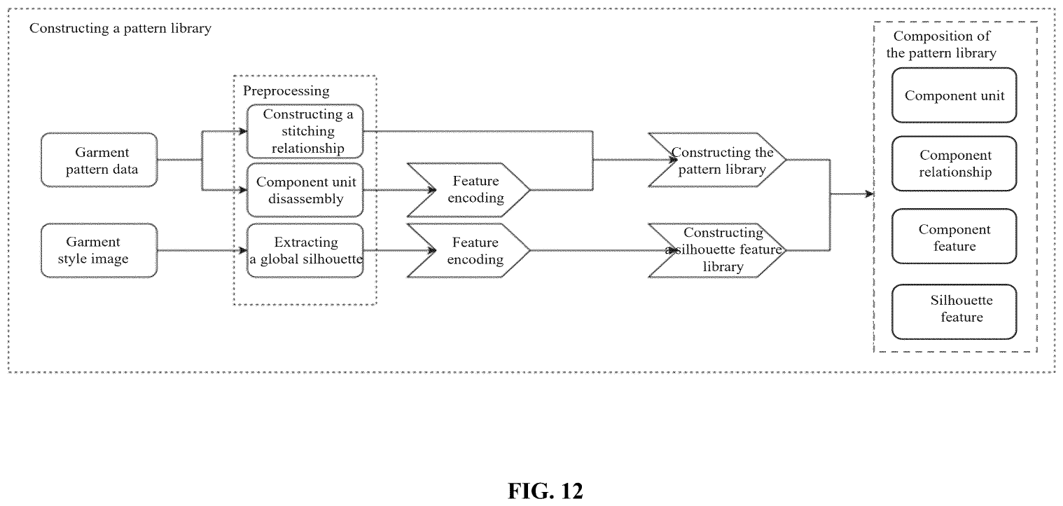

In the optional embodiment described above, the garment pattern data includes pattern design sketches of a plurality of garment pattern samples. For example, the garment pattern data includes pattern design sketches of 100 garment pattern samples. As an example, referring to FIG. 12, FIG. 12 is a schematic diagram illustrating a construction of a pattern library according to an embodiment of the present disclosure. As shown in FIG. 12, a component unit library, a component relationship library, a component feature library, and a silhouette feature library may be constructed based on the garment pattern data and the garment style drawings.

In the embodiment of the present disclosure, as an optional embodiment, the constructing the pattern library based on the garment pattern data includes the following operations.

A garment stitching relationship is extracted based on the garment pattern data, and the component relationship library is constructed based on the garment stitching relationship.

The garment pattern data is disassembled into the component units to obtain a component disassembly result, and the component unit library is constructed based on the component disassembly result.

In this optional embodiment, a garment stitching relationship may be extracted based on the garment pattern data, and the component relationship library may be constructed based on the garment stitching relationship; on the other hand, the garment pattern data may be disassembled into the component units to obtain a component disassembly result, and the component unit library may be constructed based on the component disassembly result.

In the embodiment of the present disclosure, the component unit library records component names and the feature vectors associated with the component names. On the other hand, the component relationship library records stitching relationships between components, wherein the component relationship library may record the stitching relationships between components based on a graph network. For example, as shown in FIG. 11, the graph network is a hierarchical representation structure. The hierarchical representation structure includes structural points in each prototype that have a strict correspondence with the human body structure, as well as connection relationships between the structural points. As shown in FIG. 11, there is a relationship between the upper garment and the front piece.

In the embodiment of the present disclosure, the component feature library records attributes of the component units, wherein the attributes of the component units include information such as color, size, and other related attributes of the component units. Furthermore, after obtaining the component unit most similar to the target garment through matching, the attributes of the component unit most similar to the target garment may be searched from the component feature library.

In the embodiment of the present disclosure, as an optional embodiment, the method according to the embodiment of the present disclosure further comprises the following operations.

A global silhouette is extracted based on the garment pattern data.

The global silhouette is encoded based on a feature learning algorithm to obtain a second feature encoding result.

The silhouette feature library is constructed based on the second feature encoding result.

The optional embodiment can extract a global silhouette based on the garment pattern data, encode the global silhouette based on a feature learning algorithm to obtain a second feature encoding result, and further construct the silhouette feature library based on the second feature encoding result.

In the embodiment of the present disclosure, as an optional embodiment, the matching the first feature vectors to obtain similar component units includes the following operations.

For each of the first feature vectors, a plurality of pre-selected elements in the component feature library is matched based on the first feature vector.

A similarity between each of the plurality of pre-selected elements and the first feature vector of the target garment is calculated.

A highest similarity element is determined based on the similarity between each the plurality of pre-selected elements and the first feature vector.

The similar component units are determined based on the highest similarity elements.

The optional embodiment can match the plurality of pre-selected elements in the component feature library based on the first feature vector of the target garment, calculate a similarity between each of the pre-selected elements and the first feature vector, determine the highest similarity element based on the similarity between each of the pre-selected elements and the first feature vector, and determine the similar component units based on the highest similarity elements.

In the embodiment of the present disclosure, as an optional embodiment, the method according to the embodiment of the present disclosure further comprises the following operations.

Modification and editing information for the garment pattern of the target garment is obtained.

A garment pattern of the target garment is modified based on the modification and editing information.

The optional embodiment can obtain modification and editing information for the garment pattern of the target garment, and further modify the garment pattern of the target garment based on the modification and editing information, so as to facilitate a designer to perform secondary modification on the target garment.

In the optional embodiment, for example, if a designer needs to adjust the collar of the shirt of Style B, it is only need to modify the collar in the garment pattern.

### Embodiment 6

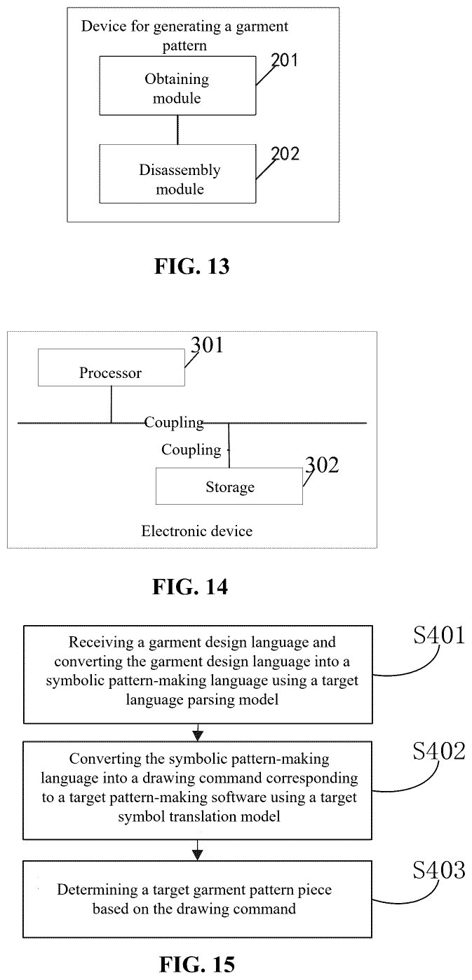

Referring to FIG. 13, FIG. 13 is a schematic diagram illustrating a structure of a device for generating a garment pattern according to an embodiment of the present disclosure. As shown in FIG. 13, the device for generating a garment pattern comprises the following modules.

An obtaining module 201 is configured to obtain a digital information carrier of a target garment; and
A disassembly module 202 is configured to disassemble the digital information carrier of the target garment into component units to obtain the component units of the target garment, and determine a garment pattern of the target garment based on the component units of the target garment.

The device according to the embodiment of the present disclosure is configured to obtain a digital information carrier of a target garment, so as to disassemble the digital information carrier of the target garment into component units to obtain the component units of the target garment, and determine a garment pattern of the target garment based on the component units of the target garment. Compared with the prior art, in contrast to the manner of retrieving garment pattern data based on images in the prior art, the present disclosure does not directly retrieve the garment pattern data. Instead, the garment pattern data of the target garment is obtained through the component units of the target garment, thereby enabling component-level matching.

It should be noted that for other detailed descriptions of the device in the present embodiment of the present disclosure, reference may be made to the related description in Embodiment 5 of the present disclosure, which will not be repeated here.

### Embodiment 7

Referring to FIG. 14, FIG. 14 is a schematic diagram illustrating a structure of an electronic device according to an embodiment of the present disclosure. As shown in FIG. 14, the electronic device according to the embodiment of the present disclosure comprises the following components.

A processor 301 is included.

A storage 302 is configured to store machine-readable instructions. When the processor executes the machine-readable instructions, the processor performs the method for generating a garment pattern of any of the above-mentioned embodiments.

The electronic device according to the embodiment of the present disclosure is configured to execute the method for generating a garment pattern, so as to obtain the digital information carrier of the target garment; disassemble the digital information carrier of the target garment into the component units to obtain the component units of the target garment; and determine the garment pattern of the target garment based on the component units of the target garment. Compared with the prior art, in contrast to the manner of retrieving garment pattern data based on images in the prior art, the present disclosure does not directly retrieve the garment pattern data. Instead, the garment pattern data of the target garment is obtained through the component units of the target garment, thereby enabling component-level matching.

### Embodiment 8

The present disclosure provides a non-transitory computer-readable storage medium storing computer programs, wherein the computer programs are executed by a processor to perform the method for generating a garment pattern of any of the above-mentioned embodiments.

The storage medium according to the embodiment of the present disclosure is configured to execute the method for generating a garment pattern, so as to obtain the digital information carrier of the target garment; disassemble the digital information carrier of the target garment into the component units to obtain the component units of the target garment; and determine the garment pattern of the target garment based on the component units of the target garment. Compared with the prior art, in contrast to the manner of retrieving garment pattern data based on images in the prior art, the present disclosure does not directly retrieve the garment pattern data. Instead, the garment pattern data of the target garment is obtained through the component units of the target garment, thereby enabling component-level matching.

In the embodiments provided by the present disclosure, it should be understood that the disclosed devices and methods can be implemented in other manners. The device embodiments described above are merely illustrative. For example, the division of units is merely a logical functional division, and in actual implementation, other division manners may be adopted. As another example, a plurality of units or components may be combined or integrated into another system, or certain features may be omitted or not performed. In addition, the couplings or direct couplings or communication connections shown or discussed may be implemented through certain communication interfaces, and indirect couplings or communication connections between devices or units may be electrical, mechanical, or other forms.

Moreover, units described as separate components may or may not be physically separated, and components illustrated as units may or may not be physical units. That is, they may be located at one place or may be distributed across a plurality of network units. Some or all of the units may be selected as needed to implement the objective of the embodiment.

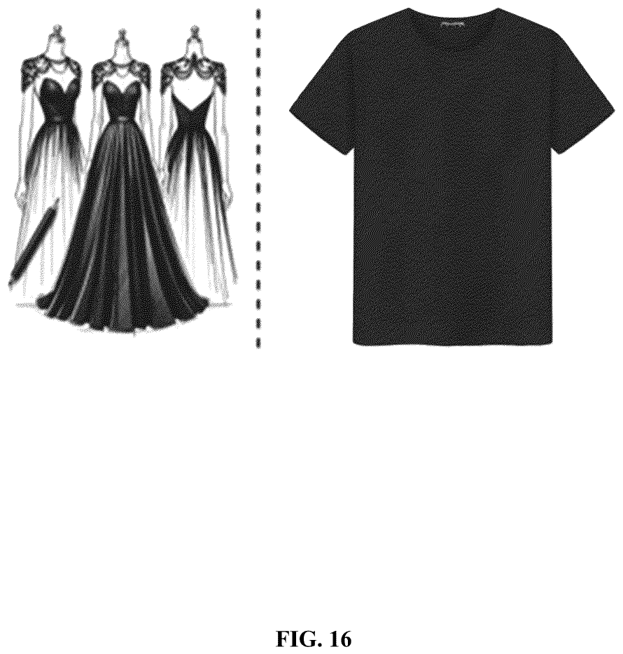

Embodiment 9 of the present disclosure provides a method for generating a garment pattern piece, which is applied to a garment pattern piece generation device. As shown in FIG. 15, the method for generating a garment pattern piece specifically comprises the following operations.
S401, a garment design language may be received, and the garment design language may be converted into a symbolic pattern-making language using a target language parsing model.
S402, the symbolic pattern-making language may be converted into a drawing command corresponding to a target pattern-making software using a target symbol translation model.
S403, a target garment pattern piece may be determined based on the drawing command.

Compared with the prior art, in the method for generating a garment pattern piece provided in Embodiment 9 of the present disclosure, after receiving the garment design language input by a user, the garment design language is converted into drawing commands through a target language parsing model and the target symbol translation model. The target garment pattern piece is then generated based on the drawing commands. The user only needs to input the garment design language during pattern making. The garment design language may include, for example, natural language, design drafts, or photographs, thereby reducing the professional skill requirements in the garment pattern piece generation process. Meanwhile, due to the high degree of automation in the entire pattern-making process, the user can simultaneously carry out a large number of garment pattern-making tasks, thereby improving the overall pattern-making efficiency. In addition, since there is a significant difference between the conversion logic of converting the garment design language into the symbolic pattern-making language and that of converting the symbolic pattern-making language into the drawing command, the garment design language is first converted into the symbolic pattern-making language using the target language parsing model, and then the symbolic pattern-making language is converted into the drawing command using the target symbol translation model. By using the symbolic pattern- making language as an intermediate representation, the operational logic of the target language parsing model and the target symbol translation model can be made clearer, the training process becomes simpler, and the amount of data required for training is reduced.

In operation S401, the garment design language may include a natural language input by a user, a design sketch uploaded by the user, a photo, or other image-based language. For example, the garment design language may be a natural language description input by the user during the pattern-making process, such as “A black, A-line dress with a fitted bodice and flaring skirt” or “ [symbol] , [symbol] ”; alternatively, the garment design language may also be a design sketch or a photo of a finished garment uploaded by the user to the garment pattern piece generation device during the pattern-making process, as shown in FIG. 16. The specific form of the garment design language may be selected based on actual design needs.

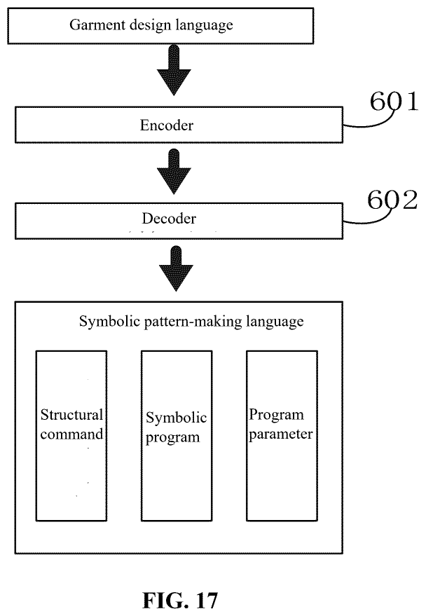

Furthermore, in operation S401, as shown in FIG. 17, the target language parsing model may include an encoder 601 and a decoder 602. The encoder 601 may be a neural network encoder configured to convert the garment design language, such as natural language, design sketches, and photos, into a feature space vector representation. The decoder 602 may be a neural network decoder configured to parse the feature space vector into a symbolic pattern-making language. As shown in FIG. 17, the symbolic pattern-making language may include structure commands, symbolic programs, and program parameters. The symbolic program may include functions such as “_make_top_bodice” for making a top and “_make_skirt” for making a skirt. The structural commands may include functions such as “Stitching”, which define the combinational relationships and logical sequences among different symbolic programs. For example, a structural command may include “stitch the top and the skirt”. The program parameters may include the runtime parameters for each function in the structural commands, such as the size parameters of the top, the size parameters of the skirt, or the like.

It is to be understood that the symbolic pattern-making language including structural commands, symbolic programs, and program parameters is merely a specific example in the embodiments of the present disclosure, and represents only one type of generalized logical abstraction of the pattern-making rules. The structural commands, symbolic programs, and program parameters are used to define the garment objects and operations involved in the pattern-making process, rather than specifying the syntax of any particular industrial pattern-making language. Since the symbolic pattern-making language is independent of the specific syntax of pattern-making software, a same target language parsing model can be used for different pattern-making software without needing to change the target language parsing model according to the software, thereby reducing the requirements for the target language parsing model and simplifying the training process of the target language parsing model.

Specifically, the target language parsing model may be a large multimodal model. The training process of the target language parsing model in the form of a large multimodal model may be performed by using a constructed standard large multimodal model as an initial language parsing model, and fine-tuning the initial language parsing model of the standard large multimodal model based on a pre-collected training dataset. The training dataset may include a plurality of training data, and the training data may be, for example, in a “style description-symbolic program-pattern piece” format.

Furthermore, in different embodiments of the present disclosure, the target pattern-making software may be a preset pattern-making software, or may be a pattern-making software included in the garment design language, such as “generating pattern pieces of a black A-line dress with a fitted bodice and flaring skirt using A pattern-making software,” which may be set based on actual needs.

Furthermore, in operation S402, the drawing command is a code segment used to generate pattern pieces and may be applied in CAD pattern-making software such as ET, Assyst, etc. For example, CAD pattern-making software such as ET, Assyst, etc. may generate corresponding pattern pieces based on the drawing command.

In operation S402, the target symbol translation model may be a neural network model that adopts a “text-to-text” conversion architecture. The input of the target symbol translation model is the symbolic pattern-making language generated in operation S401, and the output is the corresponding drawing command. During the training process of the target symbol translation model, an initial neural network model may first be constructed based on the “text-to-text” conversion architecture. Then, a large amount of training data may be used to train the initial neural network model, where the training data may be many data pairs comprising the symbolic pattern-making language and the corresponding sample drawing commands. The initial neural network model is trained based on the training data to obtain the target symbol translation model.

In operation S402, the process for determining the target garment pattern piece based on the drawing command specifically includes the following operations. The drawing command is input into the target pattern-making software, and the output result of the target pattern-making software is used as the target garment pattern piece. The target pattern-making software may be executed in the garment pattern piece generation device or an external device connected to the garment pattern piece generation device, and may be flexibly applied based on actual needs.

Furthermore, in different embodiments of the present disclosure, when the target pattern-making software is executed in the garment pattern piece generation device, the target pattern-making software used in operation S403 may be different. For different target pattern-making software, the corresponding pattern-making commands may have different syntax formats. Therefore, in the training process of the target symbol translation model in operation S402, the sample drawing commands used for training may also differ. Specifically, the sample drawing commands used for training the target symbol translation model are pattern-making commands based on the syntax format of the target pattern-making software.

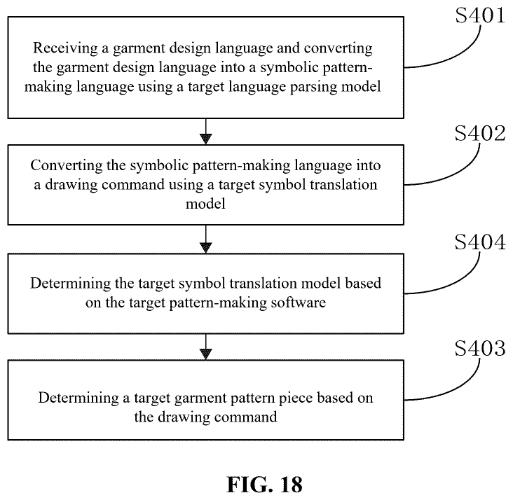

Based on the above, in some embodiments of the present disclosure, as shown in FIG. 18, the method for generating a garment pattern piece, in addition to the above-described operations S401 to S403, before converting the symbolic pattern-making language into the drawing command using the target symbol translation model in operation S403, the method for generating a garment pattern piece further comprises the following operation.
S404, the target symbol translation model may be determined based on the target pattern-making software.

Compared with the related art, in the embodiments of the present disclosure, for different types of target pattern-making software, a target symbol translation model corresponding thereto is selected to generate pattern-making commands. Each target symbol translation model is only used for generating drawing commands corresponding to one type of target pattern-making software, thereby avoiding confusion of syntax rules of different types of pattern-making software by the target symbol translation model, reducing the possibility that the target symbol translation model generates drawing commands that do not comply with the syntax rules of the target pattern-making software, and making the pattern-making commands generated by the target symbol translation model better match the target pattern-making software used in subsequent operations, so as to improve the pattern-making quality of the target pattern-making software.

Specifically, in some embodiments of the present disclosure, operation S404 may include the following operations. A target pattern-making grammar rule of the target pattern-making software is obtained; an initial symbol translation model is obtained; and the initial symbol translation model is trained using the target pattern-making grammar rule to obtain the target symbol translation model.

Specifically, training the initial symbol translation model using the target pattern-making grammar rule may involve generating a large amount of sample pattern-making language based on the target pattern-making grammar rule, and then training the constructed initial symbol translation model using the generated sample pattern-making language. Upon completion of the training, the target symbol translation model is obtained.

By performing model training of the target symbol translation model based on real-time acquisition of the target pattern-making grammar rule of the target pattern-making software, when the target pattern-making grammar rule changes, the target symbol translation model can be correspondingly adjusted, thereby enabling the pattern-making commands generated by the target symbol translation model to better match the target pattern-making software used in operation S403 and improving the pattern-making quality of the target pattern-making software.

Furthermore, in some other embodiments of the present disclosure, the determining the target symbol translation model based on the target pattern-making software includes the following operations. A preset symbol translation model list is obtained, wherein the preset symbol translation model list includes a plurality of sample symbol translation models and sample pattern-making software corresponding to each of the plurality of sample symbol translation models; and a sample symbol translation model corresponding to the target pattern-making software in the preset symbol translation model list is determined as the target symbol translation model.

A preset symbol translation model list is pre-set, wherein the preset symbol translation model list includes a plurality of pre-trained sample symbol translation models and the sample pattern-making software corresponding to each of the sample symbol translation models. When determining the target symbol translation model, the sample symbol translation model corresponding to the target pattern-making software in the symbol translation model list is directly determined as the target symbol translation model, so that the model training process can be omitted, thereby improving the determination efficiency of the target symbol translation model.

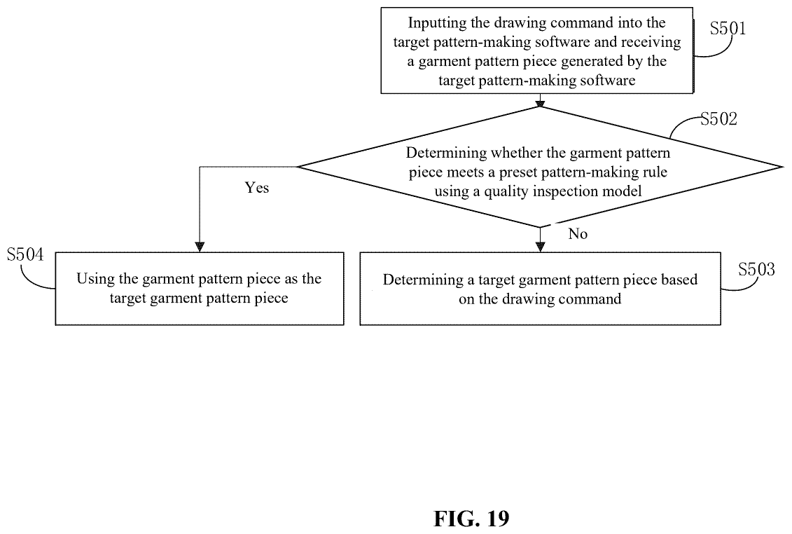

Furthermore, in operation S403, as shown in FIG. 19, the determining a target garment pattern piece based on the drawing command includes the following operations.
S501, the drawing command may be input into the target pattern-making software, and a garment pattern piece generated by the target pattern-making software may be received.
S502, whether the garment pattern piece meets a preset pattern-making rule may be determined using a quality inspection model, in response to determining that the garment pattern piece does not meet the preset pattern-making rule, operation S503 may be performed; and in response to determining that the garment pattern piece meets the preset pattern-making rule, operation S504 may be performed.
S503, the drawing command may be adjusted according to a preset pattern-making rule, the adjusted drawing command may be input into the target pattern-making software, and the target garment pattern piece generated by the target pattern-making software may be received.
S504, in response to determining that the garment pattern piece meets the preset pattern-making rule, the garment pattern piece may be used as the target garment pattern piece.

Upon receiving a garment pattern piece generated by the target pattern-making software based on the drawing command, a quality inspection model is used to detect the generated garment pattern piece and determine whether the garment pattern piece meets a preset pattern-making rule. In a case where the garment pattern piece does not meet the preset pattern-making rule, the drawing command is adjusted based on the preset pattern-making rule, and a target garment pattern piece generated by the target pattern-making software based on the adjusted drawing command is received, so as to make the generated target garment pattern piece better conform to the preset pattern-making rule and improve the pattern-making quality of the target garment pattern piece.

The quality inspection model is a mathematical model trained based on the preset pattern-making rule. The preset pattern-making rule may be a standardized pattern-making rule in the pattern-making industry or a customized pattern-making rule set according to specific requirements, and can be flexibly configured based on actual disclosure needs.

In some embodiments of the present disclosure, the quality inspection model may also specifically be a Large Multimodal Model (LMM). Furthermore, in some embodiments of the present disclosure, the target language parsing model and the quality inspection model may be the same large multimodal model trained based on a preset pattern-making rule.

The target language parsing model and the quality inspection model are the same large multimodal model, which can reduce the training process and training requirements of the model, thereby improving pattern-making efficiency and reducing pattern-making costs.

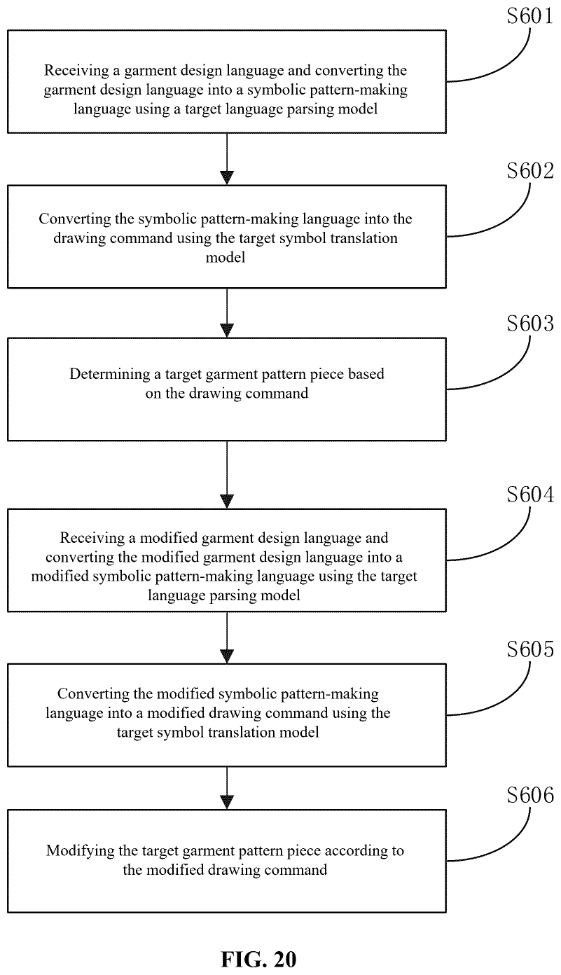

Embodiment 10 of the present disclosure provides a method for generating a garment pattern piece, which is applied to a garment pattern piece generation device. As shown in FIG. 20, the method for generating a garment pattern piece further comprises the following operations.

S601, a garment design language may be received, and the garment design language may be converted into a symbolic pattern-making language using a target language parsing model.
S602, the symbolic pattern-making language may be converted into the drawing command using the target symbol translation model.
S603, a target garment pattern piece may be determined based on the drawing command.
S604, a modified garment design language may be received, and the modified garment design language may be converted into a modified symbolic pattern-making language using the target language parsing model.
S605, the modified symbolic pattern-making language may be converted into a modified drawing command using the target symbol translation model.
S606, the target garment pattern piece may be modified according to the modified drawing command.

Compared with the related art, in the method for generating a garment pattern piece provided in Embodiment 10 of the present disclosure, after the target garment pattern piece is generated, a modified garment design language input by a user is further received, and the target garment pattern piece is modified based on a modified drawing command generated from the modified garment design language, thereby enabling convenient modification of the target garment pattern piece.

It is understood that operations S601 to S603 in the method for generating a garment pattern piece of Embodiment 10 of the present disclosure are generally the same as operations S401 to S403 in the aforementioned embodiments, and specific details may refer to the descriptions in the aforementioned embodiments.

Furthermore, in operation S604, the language type of the modified garment design language may be the same as or different from that of the garment design language in operation S401. For example, both may be natural language, or the garment design language in operation S401 may be an image language such as a design drawing, while the modified garment design language may be natural language.

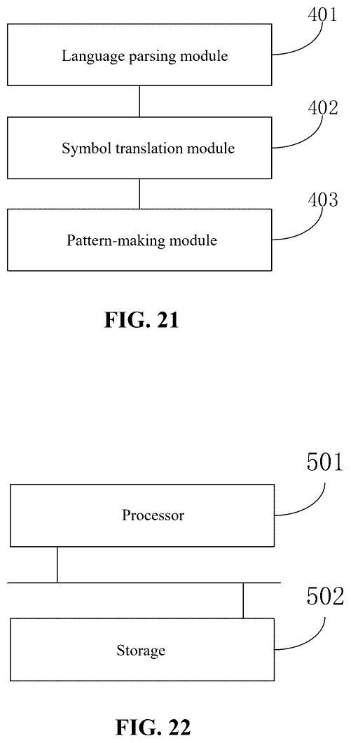

The present disclosure provides a device for generating a garment pattern piece, according to Embodiment 11. As shown in FIG. 21, the device comprises the following modules. A language parsing module 401 is configured to receive a garment design language and convert the garment design language into a symbolic pattern-making language using a target language parsing model. A symbol translation module 402 is configured to convert the symbolic pattern-making language into a drawing command corresponding to the target pattern-making software using a target symbol translation model. A pattern-making module 403 is configured to determine a target garment pattern piece based on the drawing command.

Compared with the prior art,, in the device for generating the garment pattern piece provided in Embodiment 11 of the present disclosure, after a garment design language is received by the language parsing module 401, the garment design language is converted into the drawing command through the target language parsing model in the language parsing module 401 and the target symbol translation model in the symbol translation module 402, and pattern-making software in the pattern-making module 403 is used to perform pattern-making based on the drawing command to obtain the target garment pattern piece. During pattern-making, a user only needs to input the garment design language, which may be natural language, design drafts, photos, or the like, thereby reducing the professional skill requirements in the garment pattern piece preparation process. Meanwhile, since the entire pattern-making process is highly automated, the user can perform a large number of garment pattern-making tasks simultaneously, thereby improving overall pattern-making efficiency.

The symbol translation module 402 is further configured to determine the target symbol translation model based on the target pattern-making software before converting the symbolic pattern-making language into the drawing command using the target symbol translation model.

The symbol translation module 402 is further configured to obtain a target pattern- making grammar rule of the target pattern-making software, obtain an initial symbol translation model, and train the initial symbol translation model using the target pattern-making grammar rule to obtain the target symbol translation model.

The symbol translation module 402 is further configured to obtain the preset symbol translation model list, wherein the preset symbol translation model list includes the plurality of sample symbol translation models and the sample pattern-making software corresponding to each of the plurality of sample symbol translation models, and determine the sample symbol translation model corresponding to the target pattern-making software in the preset symbol translation model list as the target symbol translation model.

The pattern-making module 403 is further configured to input the drawing command into the target pattern-making software and receive the garment pattern piece generated by the target pattern-making software; determine whether the garment pattern piece meets the preset pattern-making rule using the quality inspection model; in response to determining that the garment pattern piece does not meet the preset pattern-making rule, adjust the drawing command according to the preset pattern-making rule, input the adjusted the drawing command into the target pattern-making software, and receive the target garment pattern piece generated by the target pattern-making software; and in response to determining that the garment pattern piece meets the preset pattern-making rule, use the garment pattern piece as the target garment pattern piece. In different embodiments of the present disclosure, the target pattern-making software may be directly executed in the pattern-making module 403, and the pattern-making module 403 directly uses the target pattern-making software running therein to generate the target garment pattern piece; alternatively, the target pattern-making software may be executed in another external device connected to the pattern-making module 403, and the pattern-making module 403 sends the drawing command to the external device and receives the target garment pattern piece returned by the external device.

In addition, the language parsing module 401 is further configured to receive the modified garment design language and convert the modified garment design language into the modified symbolic pattern-making language using the target language parsing model; the symbol translation module 402 is further configured to convert the modified symbolic pattern-making language into a modified drawing command using the target symbol translation model; the pattern-making module 403 is further configured to modify the target garment pattern piece according to the modified drawing command.

Embodiment 12 of the present disclosure provides an electronic device, as shown in FIG. 22, comprises at least one processor 501, and a storage 502 in communication with the at least one processor 501. The storage 502 stores instructions executable by the at least one processor 501 that, when executed by the at least one processor 501, cause the at least one processor 501 to perform the method described in the above embodiments.

The storage and the processor are connected via a bus, and the bus may include any number of interconnected buses and bridges. The bus connects various circuits of the one or more processors and the storage. The bus may also connect various other circuits such as peripheral devices, voltage regulators, and power management circuits, which are well known in the art and thus will not be further described herein. The bus interface provides an interface between the bus and a transceiver. The transceiver may be a single element or a plurality of elements, such as a plurality of receivers and transmitters, and provides a unit for communication with various other devices over a transmission medium. Data processed by the processor is transmitted over a wireless medium via an antenna. Furthermore, the antenna also receives data and transmits the data to the processor.

The processor is responsible for managing the bus and general processing, and may also provide various functions, including timing, peripheral interfacing, voltage regulation, power management, and other control functions. The storage may be used to store data used by the processor when performing operations.

In several embodiments provided in the present disclosure, it should be understood that the disclosed devices and methods may also be implemented in other ways. The device embodiments described above are merely illustrative. For example, the flowcharts and block diagrams in the accompanying drawings illustrate possible architectures, functionalities, and operations of devices, methods, and computer program products according to a plurality of embodiments of the present disclosure. In this regard, each block in the flowcharts or block diagrams may represent a module, a program segment, or a portion of code, which contains one or more executable instructions for implementing specified logical functions. It should also be noted that, in some alternative implementations, the functions indicated in the blocks may occur in an order different from that illustrated in the accompanying figures. For example, two consecutive blocks may be executed substantially in parallel, or sometimes in a reverse order, depending on the functionalities involved. It should also be noted that each block in the block diagrams and/or flowcharts, as well as combinations of blocks in the block diagrams and/or flowcharts, may be implemented by a dedicated hardware-based system that performs the specified functions or actions, or by a combination of dedicated hardware and computer instructions.

In addition, in various embodiments of the present disclosure, the functional modules may be integrated to form an independent part, or each module may exist independently, or two or more modules may be integrated to form an independent part.

In the above embodiments, all or part of the functionalities may be implemented through software, hardware, firmware, or any combination thereof. When implemented using software, the functionalities may be implemented wholly or partly in the form of a computer program product. The computer program product includes one or more computer instructions, which, when loaded onto and executed on a device, cause all or part of the processes or functions described in the embodiments of the present disclosure to be performed. The computer instructions may be stored in a computer-readable storage medium, or transmitted from one computer-readable storage medium to another computer-readable storage medium. For example, the computer instructions may be transmitted from one website, computer, server, or data center to another website, computer, server, or data center via a wired manner (e.g., coaxial cable, optical fiber, digital subscriber line) or a wireless manner (e.g., infrared, radio, microwave, etc.). The computer-readable storage medium may be any available medium that may be accessed by a device, or a data storage device such as a server or data center that integrates one or more available media. The available media may be magnetic media (e.g., floppy disks, hard disks, magnetic tapes), optical media (e.g., digital video disks (DVDs)), or semiconductor media (e.g., solid-state drives).

Those of ordinary skill in the art may understand that all or part of the steps of the above-described embodiments may be implemented by hardware, or may be implemented by instructing relevant hardware through a program. The program may be stored in a computer-readable storage medium. The aforementioned storage medium may be a read-only memory, a magnetic disk, an optical disk, or the like.

When the described functions are implemented in the form of software functional modules and sold or used as independent products, the software functional modules may be stored in a computer-readable storage medium. Based on this understanding, the technical solutions of the present disclosure, or the parts thereof that essentially constitute the contribution to the prior art, may be embodied in the form of a software product. The computer software product is stored in a storage medium and includes a plurality of instructions for causing a computer device (such as a personal computer, a server, or a network device) to execute all or part of the steps of the methods described in various embodiments of the present disclosure. The aforementioned storage medium include USB flash drives, mobile hard disks, read-only memory (ROM, Read-Only Memory), random access memory (RAM, Random Access Memory), magnetic disks, optical disks, or various media capable of storing program code.

The foregoing is merely exemplary embodiments of the present disclosure and is not intended to limit the scope of protection of the present disclosure. Various modifications and variations may be made to the present disclosure by those skilled in the art. Any modifications, equivalent substitutions, improvements, etc. made within the spirit and principle of the present disclosure shall be included within the scope of protection of the present disclosure. Therefore, the scope of protection of the present disclosure shall be defined by the claims. It should be noted that similar reference numerals and letters in the following drawings represent similar items, and once an item is defined in one drawing, it does not require further definition and explanation in the subsequent drawings.

It should be noted that, in the present description, relational terms such as “first” and “second” are merely used to distinguish one entity or operation from another entity or operation, and do not necessarily imply any actual relationship or order between such entities or operations Furthermore, the terms “comprise,” “include,” or any other variations thereof are intended to cover non-exclusive inclusion, such that a process, method, article, or device that comprises a list of elements is not limited to those elements, but may include other elements not explicitly listed or may include elements inherent to such process, method, article, or device. Without further limitations, an element defined by the phrase “comprising a . . .” does not exclude the existence of additional identical elements in the process, method, article, or device that comprises the element.

What is claimed is:

1. A method for generating a garment design drawing, comprising:
receiving design intent data and/or design materials;
initializing the design intent data to obtain a visual design drawing; and/or encoding the design materials to obtain a material feature code;
generating a target design drawing by inputting the material feature code and/or the visual design drawing into a pre-built generative network; and
outputting the target design drawing.

2. The method according to claim 1, wherein the design intent data includes one or more of natural language description data, a style drawing, and a line drawing; and
the design materials include one or more of a text material, an image material, and a graphic material.

3. The method according to claim 1, wherein the encoding the design materials to obtain a material feature code includes:
determining a target encoder corresponding to each of the design materials; wherein the target encoder includes a text encoder, an image encoder, or a graphics encoder; and
encoding the design materials based on the target encoders to obtain the material feature code.

4. The method according to claim 1, further comprising:
in response to a modification instruction for the target design drawing, modifying the target design drawing to obtain a modified design drawing;
determining the modified design drawing as the design intent data and initializing the design intent data to obtain the visual design drawing; and
receiving a new design material and encoding the design materials including the new design material to obtain a material feature code.

5. A method for generating a garment pattern, comprising:
obtaining a digital information carrier of a target garment; and
disassembling the digital information carrier of the target garment into component units to obtain the component units of the target garment, and determining the garment pattern of the target garment based on the component units of the target garment.

6. The method according to claim 5, wherein the determining the garment pattern of the target garment based on the component units of the target garment includes:
extracting first feature vectors of the component units of the target garment;
matching the first feature vectors to obtain similar component units;
obtaining stitching lines of the similar component units and pattern information of the similar component units; and
determining the garment pattern of the target garment based on the pattern information of the similar component units and the stitching lines of the similar component units.

7. The method according to claim 6, further comprising:
optimizing the stitching lines of the similar component units, wherein an optimization of a stitching line of the similar component units includes modifying a length of the stitching line of the similar component units and modifying a curvature of the stitching line of the similar component units.

8. The method according to claim 6, further comprising:
determining a silhouette of the target garment based on the digital information carrier of the target garment; and
determining the garment pattern of the target garment based on the silhouette of the target garment.

9. The method according to claim 8, further comprising:
constructing a pattern library, the pattern library including at least a component unit library, a component relationship library, a component feature library, and a silhouette feature library, the component unit library being configured to match the similar component units, the component relationship library being configured to match the stitching lines of the similar component units, the component feature library being configured to match the pattern information of the similar component units, and the silhouette feature library being configured to extract the silhouette of the target garment.

10. The method according to claim 9, wherein the constructing a pattern library includes:
obtaining garment pattern data; and
constructing the pattern library based on the garment pattern data.

11. The method according to claim 10, wherein the constructing the pattern library based on the garment pattern data includes:
extracting a garment stitching relationship based on the garment pattern data and constructing the component relationship library based on the garment stitching relationship; and
disassembling the garment pattern data into the component units to obtain a component disassembly result, and constructing the component unit library based on the component disassembly result.

12. The method according to claim 10, further comprising:
extracting a global silhouette based on the garment pattern data;
encoding the global silhouette based on a feature learning algorithm to obtain a second feature encoding result; and
constructing the silhouette feature library based on the second feature encoding result.

13. The method according to claim 9, wherein the matching the first feature vectors to obtain similar component units includes:
for each of the first feature vectors,
matching a plurality of pre-selected elements in the component feature library based on the first feature vector;
calculating a similarity between each of the plurality of pre-selected elements and the first feature vector; and
determining a highest similarity element based on the similarity between each of the plurality of pre-selected elements and the first feature vector; and
determining the similar component units based on the highest similarity elements.

14. The method according to claim 5, further comprising:
obtaining modification and editing information for the garment pattern of the target garment; and
modifying the garment pattern of the target garment based on the modification and editing information.

15. A method for generating a garment pattern piece, comprising:
receiving a garment design language and converting the garment design language into a symbolic pattern-making language using a target language parsing model;
converting the symbolic pattern-making language into a drawing command corresponding to a target pattern-making software using a target symbol translation model; and
determining a target garment pattern piece based on the drawing command.

16. The method according to claim 15, wherein before converting the symbolic pattern-making language into the drawing command using the target symbol translation model, the method further comprises:
determining the target symbol translation model based on the target pattern-making software.

17. The method according to claim 16, wherein the determining the target symbol translation model based on the target pattern-making software includes:
obtaining a target pattern-making grammar rule of the target pattern-making software;
obtaining an initial symbol translation model; and
training the initial symbol translation model using the target pattern-making grammar rule to obtain the target symbol translation model.

18. The method according to claim 16, wherein the determining the target symbol translation model based on the target pattern-making software includes:
obtaining a preset symbol translation model list, wherein the preset symbol translation model list includes a plurality of sample symbol translation models and sample pattern-making software corresponding to each of the plurality of sample symbol translation models; and
determining a sample symbol translation model corresponding to the target pattern-making software in the preset symbol translation model list as the target symbol translation model.

19. The method according to claim 15, wherein the determining a target garment pattern piece based on the drawing command includes:
inputting the drawing command into the target pattern-making software and receiving a garment pattern piece generated by the target pattern-making software;
determining whether the garment pattern piece meets a preset pattern-making rule using a quality inspection model;
in response to determining that the garment pattern piece does not meet the preset pattern-making rule, adjusting the drawing command according to the preset pattern-making rule, inputting the adjusted drawing command into the target pattern-making software, and receiving the target garment pattern piece generated by the target pattern-making software; and
in response to determining that the garment pattern piece meets the preset pattern-making rule, using the garment pattern piece as the target garment pattern piece.

20. The method according to claim 15, further comprising:
receiving a modified garment design language and converting the modified garment design language into a modified symbolic pattern-making language using the target language parsing model;
converting the modified symbolic pattern-making language into a modified drawing command using the target symbol translation model; and
modifying the target garment pattern piece according to the modified drawing command.
